(19) United States
(12) Patent Application Publication
(10) Pub. No.: US 2025/0294767 A1
(43) Pub. Date: Sep. 18, 2025

(54) SEMICONDUCTOR STORAGE DEVICE AND METHOD OF MANUFACTURING SEMICONDUCTOR STORAGE DEVICE

(71) Applicant: Kioxia Corporation, Tokyo (JP)

(72) Inventor: Tatsuya KATO, Yokkaichi Mie (JP)

(73) Assignee: Kioxia Corporation, Tokyo (JP)

(21) Appl. No.: 19/075,033

(22) Filed: Mar. 10, 2025

(30) Foreign Application Priority Data
Mar. 18, 2024 (JP) 2024-042500

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

A semiconductor storage device according to an embodiment includes a multi-layered body and a contact. The multi-layered body includes a plurality of gate electrode layers and a plurality of insulating layers. The plurality of gate electrode layers include a first gate electrode layer and a second gate electrode layer. The first gate electrode layer is connected to the contact in a second direction. The second gate electrode layer is apart from the contact in the second direction. The first gate electrode layer includes a first conductive portion and a first insulating film. The second gate electrode layer includes a second conductive portion and a second insulating film.

### CROSS-REFERENCE TO RELATED APPLICATION

Priority is claimed on Japanese Patent Application No. 2024-042500, filed Mar. 18, 2024, the content of which is incorporated herein by reference.

### FIELD

An embodiment of the present invention relates to a semiconductor storage device and a method of manufacturing the semiconductor storage device.

### BACKGROUND ART

NAND-type flash memories including three-dimensionally disposed memory cells are known.

### BRIEF DESCRIPTION OF THE DRAWINGS

FIG. 1 is a block diagram showing a part of a semiconductor storage device of an embodiment.

FIG. 2 is a diagram showing an equivalent circuit of a part of a memory cell array of the embodiment.

FIG. 3 is a cross-sectional view showing a part of the semiconductor storage device of the embodiment.

FIG. 4 is an enlarged cross-sectional view showing a region surrounded by line F4 of the memory cell array shown in FIG. 3.

FIG. 5 is a cross-sectional view along line F5-F5 of the memory cell array shown in FIG. 4.

FIG. 6 is an enlarged cross-sectional view showing a region surrounded by line F6 of the memory cell array shown in FIG. 4.

FIG. 7 is a cross-sectional view along line F7-F7 of the memory cell array shown in FIG. 3.

FIG. 8 is a cross-sectional view showing the memory cell array of the embodiment from above.

FIG. 9 is a cross-sectional view along line F9-F9 of the memory cell array shown in FIG. 8.

FIG. 10 is an enlarged cross-sectional view showing a region surrounded by line F10 of the memory cell array shown in FIG. 9.

FIG. 11 is a cross-sectional view along line F11-F11 of the memory cell array shown in FIG. 10.

FIG. 12 is a cross-sectional view along line F12-F12 of the memory cell array shown in FIG. 10.

FIG. 13A is a cross-sectional view for explaining a method of manufacturing the semiconductor storage device of the embodiment.

FIG. 13B is a cross-sectional view for explaining the method of manufacturing the semiconductor storage device of the embodiment.

FIG. 13C is a cross-sectional view for explaining the method of manufacturing the semiconductor storage device of the embodiment.

FIG. 13D is a cross-sectional view for explaining the method of manufacturing the semiconductor storage device of the embodiment.

FIG. 13E is a cross-sectional view for explaining the method of manufacturing the semiconductor storage device of the embodiment.

FIG. 13F is a cross-sectional view for explaining the method of manufacturing the semiconductor storage device of the embodiment.

FIG. 13G is a cross-sectional view for explaining the method of manufacturing the semiconductor storage device of the embodiment.

FIG. 13H is a cross-sectional view for explaining the method of manufacturing the semiconductor storage device of the embodiment.

FIG. 14A is a cross-sectional view for explaining the method of manufacturing the semiconductor storage device of the embodiment.

FIG. 14B is a cross-sectional view for explaining the method of manufacturing the semiconductor storage device of the embodiment.

FIG. 14C is a cross-sectional view for explaining the method of manufacturing the semiconductor storage device of the embodiment.

FIG. 14D is a cross-sectional view for explaining the method of manufacturing the semiconductor storage device of the embodiment.

FIG. 14E is a cross-sectional view for explaining the method of manufacturing the semiconductor storage device of the embodiment.

FIG. 15 is a cross-sectional view showing a part of a semiconductor storage device of a first example.

FIG. 16A is a cross-sectional view for explaining a method of manufacturing the semiconductor storage device of the first example.

FIG. 16B is a cross-sectional view for explaining the method of manufacturing the semiconductor storage device of the first example.

FIG. 16C is a cross-sectional view for explaining the method of manufacturing the semiconductor storage device of the first example.

FIG. 16D is a cross-sectional view for explaining the method of manufacturing the semiconductor storage device of the first example.

FIG. 17 is a cross-sectional view showing a part of a semiconductor storage device of a second example.

FIG. 18A is a cross-sectional view for explaining a method of manufacturing the semiconductor storage device of the second example.

FIG. 18B is a cross-sectional view for explaining the method of manufacturing the semiconductor storage device of the second example.

FIG. 18C is a cross-sectional view for explaining the method of manufacturing the semiconductor storage device of the second example.

FIG. 18D is a cross-sectional view for explaining the method of manufacturing the semiconductor storage device of the second example.

### DETAILED DESCRIPTION

A semiconductor storage device according to an embodiment includes a multi-layered body and a contact. The multi-layered body includes a plurality of gate electrode layers and a plurality of insulating layers. The plurality of gate electrode layers and the plurality of insulating layers are alternately stacked one by one in a first direction. The contact extends in the first direction within the multi-layered body. The contact has conductivity. The plurality of gate electrode layers include a first gate electrode layer and a second gate electrode layer. The contact penetrates the first gate electrode layer in the first direction. The first gate electrode layer is connected to the contact in a second direction intersecting the first direction. The second gate electrode layer is adjacent to the first gate electrode layer in the first direction among the plurality of gate electrode layers. The contact penetrates the second gate electrode layer in the first direction. The second gate electrode layer is apart from the contact in the second direction. The plurality of insulating layers include a first insulating layer between the first gate electrode layer and the second gate electrode layer in the first direction. The first gate electrode layer has a first conductive portion and a first insulating film. The first insulating film is between the first conductive portion and the first insulating layer. The first insulating film includes a portion extending in the second direction. The second gate electrode layer has a second conductive portion and a second insulating film. The second insulating film is between the second conductive portion and the first insulating layer. The second insulating film includes a portion extending in the second direction. A shortest distance in the second direction between a center of the contact in the second direction and the first insulating film is smaller than or equal to a shortest distance in the second direction between the center of the contact in the second direction and the second insulating film.

Hereinafter, a semiconductor storage device and a method of manufacturing the semiconductor storage device of the embodiment will be described with reference to the drawings. In the following description, components having the same or similar functions will be denoted by the same reference signs. Also, duplicate description of the components may be omitted. In the following description, when a reference sign is appended with a number or an alphabetical letter at the end for distinction, the number or the alphabetical letter at the end may be omitted when there is no need for distinguishing.

In the present application, terms are defined as follows. “Parallel”, “orthogonal”, or “the same” may include a case of “substantially parallel”, “substantially orthogonal”, or “substantially the same”. “Connection” is not limited to a case of being mechanically connected, and may also include a case of being electrically connected. That is, “connection” is not limited to a case in which a plurality of elements are directly connected, and may include a case in which a plurality of elements are connected with another element interposed therebetween. “Overlapping” is not limited to a case in which a plurality of elements are in contact with each other, and can also include a case in which a plurality of elements are separated (a case in which projection images of the plurality of elements overlap each other when viewed from a certain direction).

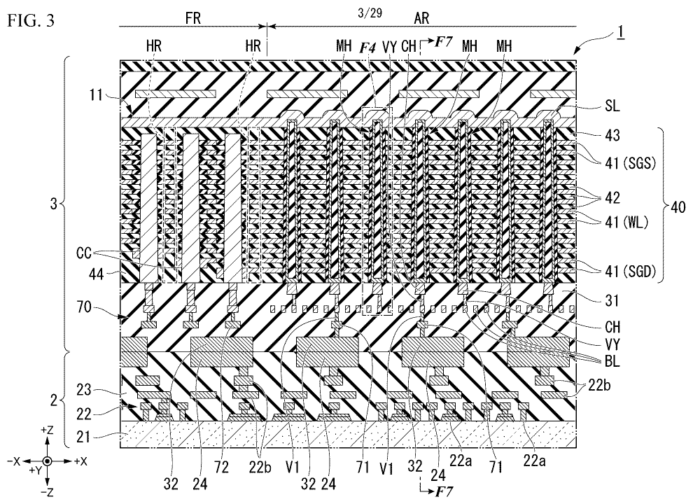

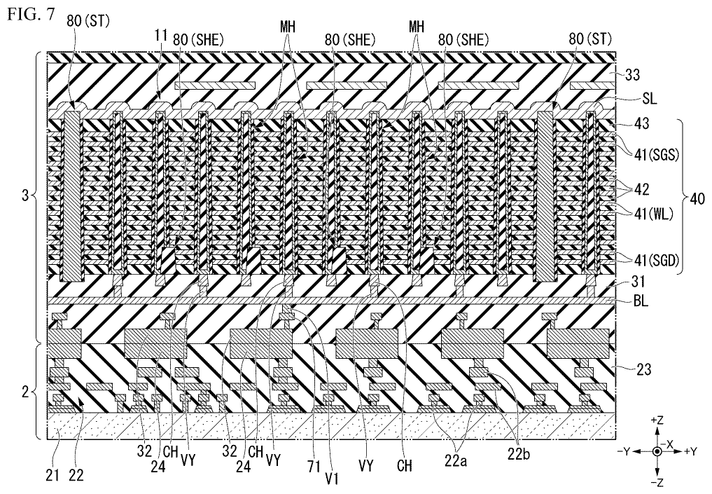

A +X direction, a −X direction, a +Y direction, a −Y direction, a +Z direction, and a −Z direction are defined as follows. The +X direction is a direction in which a word line WL to be described later extends (refer to FIG. 3). The −X direction is a direction opposite to the +X direction. In a case in which the +X direction and the −X direction do not need to be distinguished from each other, they will be simply referred to as an “X direction”. The +Y direction is a direction that intersects (for example, is orthogonal to) the X direction. The +Y direction is a direction in which a bit line BL extends (refer to FIG. 7). The −Y direction is a direction opposite to the +Y direction. In a case in which the +Y direction and the −Y direction do not need to be distinguished from each other, they will be simply referred to as a “Y direction”. The +Z direction is a direction that intersects (for example, is orthogonal to) the X direction and the Y direction. The +Z direction is a direction toward a multi-layered body 40 from the bit line BL to be described later (refer to FIG. 3). The −Z direction is a direction opposite to the +Z direction. In a case in which the +Z direction and the −Z direction do not need to be distinguished from each other, they will be simply referred to as a “Z direction”. In the present application, a side in the +Z direction may be referred to using “upper” and a side in the −Z direction may be referred to using “lower”. Also, in the following description, a position in the Z direction may be referred to using a “height”. However, these expressions are for convenience of explanation only and do not define the direction of gravity. The Z direction is an example of a “first direction”. The X direction corresponds to an example of a “second direction”. In the drawings described below, illustration of components not related to the description may be omitted.

### Embodiment

### 1. Configuration of Semiconductor Storage Device

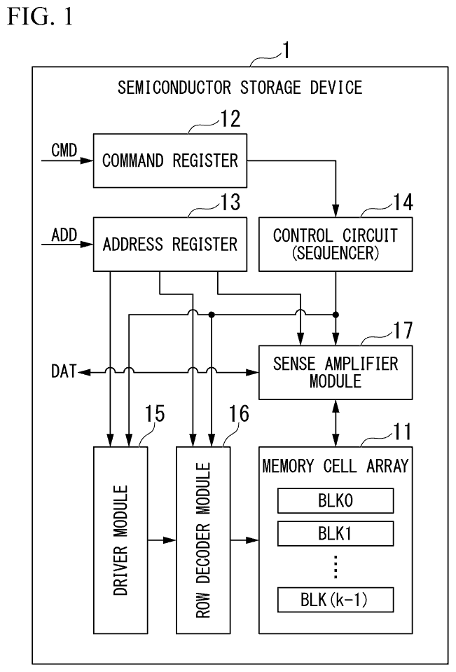

FIG. 1 is a block diagram showing a part of a semiconductor storage device 1 of an embodiment. The semiconductor storage device 1 is, for example, a nonvolatile semiconductor storage device. The semiconductor storage device 1 is a NAND-type flash memory. The semiconductor storage device 1 can be connected to an external host device. The semiconductor storage device 1 is used as a storage space for the host device. The semiconductor storage device 1 includes, for example, a memory cell array 11, a command register 12, an address register 13, a control circuit (sequencer) 14, a driver module 15, a row decoder module 16, and a sense amplifier module 17.

The memory cell array 11 includes a plurality of blocks BLK0 to BLK (k-1) (k is an integer of 1 or more). The block BLK is a set of memory cell transistors. The block BLK is used as units of data erasure. A plurality of bit lines and a plurality of word lines are provided in the memory cell array 11. Each of the memory cell transistors is associated with one bit line and one word line.

The command register 12 holds a command CMD received by the semiconductor storage device 1 from the host device. The address register 13 holds address information ADD received by the semiconductor storage device 1 from the host device. The address information ADD is used to select a block BLK, a word line, and a bit line. The control circuit 14 controls various operations of the semiconductor storage device 1. For example, the control circuit 14 executes a write operation, a read operation, an erase operation, or the like of data based on the command CMD held in the command register 12.

The driver module 15 includes a voltage generation circuit and generates voltages used in various operations of the semiconductor storage device 1. The row decoder module 16 transfers a voltage applied to a signal line corresponding to a selected word line to the selected word line. The sense amplifier module 17 applies a desired voltage to each bit line in the write operation. In the read operation, the sense amplifier module 17 determines data stored in each memory cell transistor based on a voltage of each bit line, and transfers the determination result to the host device as read data DAT.

### 2. Electrical Configuration of Memory Cell Array

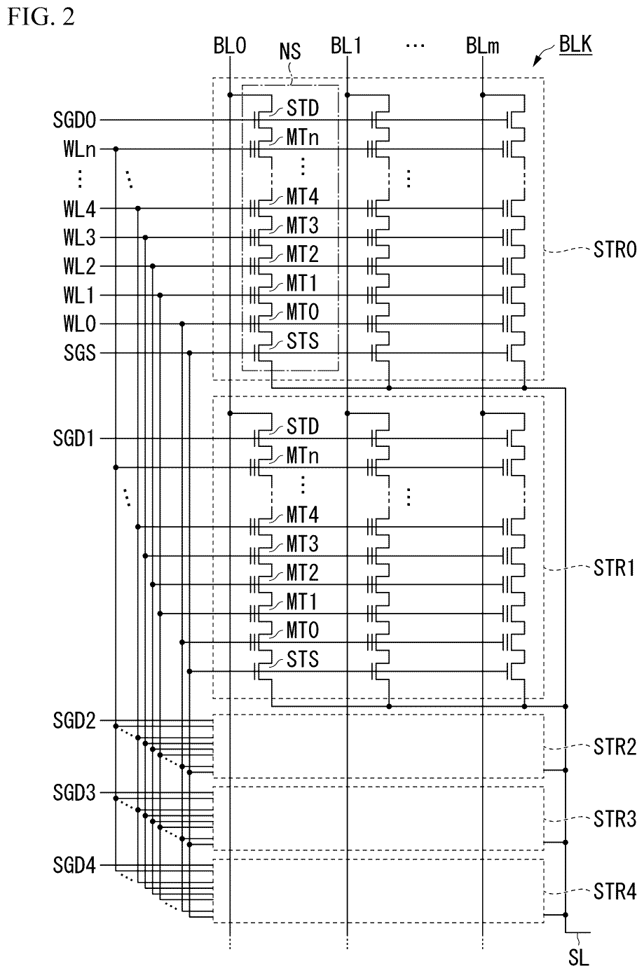

FIG. 2 is a diagram showing an equivalent circuit of a part of the memory cell array 11. FIG. 2 shows one block BLK included in the memory cell array 11. The block BLK includes a plurality of strings STR (for example, five strings STR0 to STR4).

Each string STR includes a plurality of NAND strings NS that are respectively associated with bit lines BL0 to BLm (m is an integer of 1 or more). Each NAND string NS includes a plurality of memory cell transistors MT0 to MTn (n is an integer of 1 or more), one or more drain-side selection transistors STD, and one or more source-side selection transistors STS.

In each NAND string NS, the memory cell transistors MT0 to MTn are connected in series. Each of the memory cell transistors MT includes a control gate and a charge storage portion. The control gate of the memory cell transistor MT is connected to any one of word lines WL0 to WLn. In each memory cell transistor MT, electric charge is stored in the charge storage portion according to a voltage applied to the control gate via the word line WL. Therefore, each memory cell transistor MT holds data non-volatilely.

A drain of the drain-side selection transistor STD is connected to the bit line BL corresponding to the NAND string NS. A source of the drain-side selection transistor STD is connected to one end of the memory cell transistors MT0 to MTn connected in series. A control gate of the drain-side selection transistor STD is connected to any one of the drain-side selection gate lines SGD0 to SGD3. The drain-side selection transistor STD is electrically connected to the row decoder module 16 via the drain-side selection gate line SGD. The drain-side selection transistor STD connects the NAND string NS and the bit line BL when a predetermined voltage is applied to the corresponding drain-side selection gate line SGD.

A drain of the source-side selection transistor STS is connected to the other end of the memory cell transistors MT0 to MTn connected in series. A source of the source-side selection transistor STS is connected to a source line SL. A control gate of the source-side selection transistor STS is connected to a source-side selection gate line SGS. The source-side selection transistor STS connects the NAND string NS and the source line SL when a predetermined voltage is applied to the source-side selection gate line SGS.

In the same block BLK, the control gates of the memory cell transistors MT0 to MTn are commonly connected to the corresponding word lines WL0 to WLn, respectively. In the same string STR, the control gates of the drain-side selection transistors STD are commonly connected to the corresponding drain-side selection gate line SGD. The control gates of the source-side selection transistors STS are commonly connected to the source-side selection gate line SGS. In the memory cell array 11, the bit line BL is shared by the NAND strings NS to which the same column address is assigned in the plurality of strings STR.

### 3. Structure of Semiconductor Storage Device

Next, a structure of the semiconductor storage device 1 will be described. FIG. 3 is a cross-sectional view showing a part of the semiconductor storage device 1. The semiconductor storage device 1 includes, for example, a first chip 2 and a second chip 3. The second chip 3 is a chip adhered to the first chip 2.

### 3.1 First Chip

The first chip 2 is a circuit chip including peripheral circuits. The first chip 2 includes, for example, a semiconductor substrate 21, a peripheral circuit 22, an insulating portion 23, and a plurality of pads 24.

The semiconductor substrate 21 is a substrate, for example, serving as a base of the first chip 2. At least a part of the semiconductor substrate 21 has a plate shape extending in the X direction and the Y direction. The semiconductor substrate 21 is formed of a semiconductor material such as, for example, silicon.

The peripheral circuit 22 is a circuit configured to cause the memory cell array 11 described above to function. The peripheral circuit 22 includes a plurality of transistors 22a and a plurality of interconnections 22b. The peripheral circuit 22 includes one or more of the command register 12, the address register 13, the control circuit 14, the driver module 15, the row decoder module 16, and the sense amplifier module 17 described above. The insulating portion 23 covers the peripheral circuit 22. The plurality of pads 24 are provided on a surface of the insulating portion 23. The pads 24 are each electrically connected to the peripheral circuit 22.

### 3.2 Second Chip

The second chip 3 is an array chip that includes the memory cell array 11. The second chip 3 includes, for example, the memory cell array 11, an insulating portion 31, and a plurality of pads 32. Here, the insulating portion 31 and the plurality of pads 32 will be described, and the memory cell array 11 will be described later.

The insulating portion 31 covers the memory cell array 11 from the side in the-Z direction. The plurality of pads 32 are provided on a surface of the insulating portion 31. The pads 32 are each electrically connected to an interconnection (for example, an interconnection 71 or an interconnection 72) included in an interconnection portion 70 of the memory cell array 11 to be described later. In the present embodiment, the plurality of pads 24 of the first chip 2 and the plurality of pads 32 of the second chip 3 are adhered together with their surfaces facing each other. Therefore, the first chip 2 and the second chip 3 are integrated.

### 4. Memory Cell Array

Next the memory cell array 11 will be described.

As shown in FIG. 3, the memory cell array 11 includes an array region AR and a hook-up region FR. A plurality of memory pillars MH to be described later are provided in the array region AR. The array region AR is a region in which data can be stored. A plurality of contacts CC to be described late are provided in the hook-up region FR. The array region AR is a region in which a plurality of gate electrode layers 41 to be described later and the interconnection portion 70 are connected. The hook-up region FR is provided, for example, on both sides of the array region AR in the X direction.

As shown in FIG. 3, the memory cell array 11 includes, for example, a multi-layered body 40, the source line SL, the plurality of memory pillars MH, a plurality of bit lines BL, a plurality of contacts CH for memory pillars, a plurality of contacts VY for memory pillars, the contacts CC for conductive layers, the interconnection portion 70, a support HR, and a plurality of dividing portions 80 (refer to FIG. 7).

### 4.1 Multi-Layered Body

First, the multi-layered body 40 will be described.

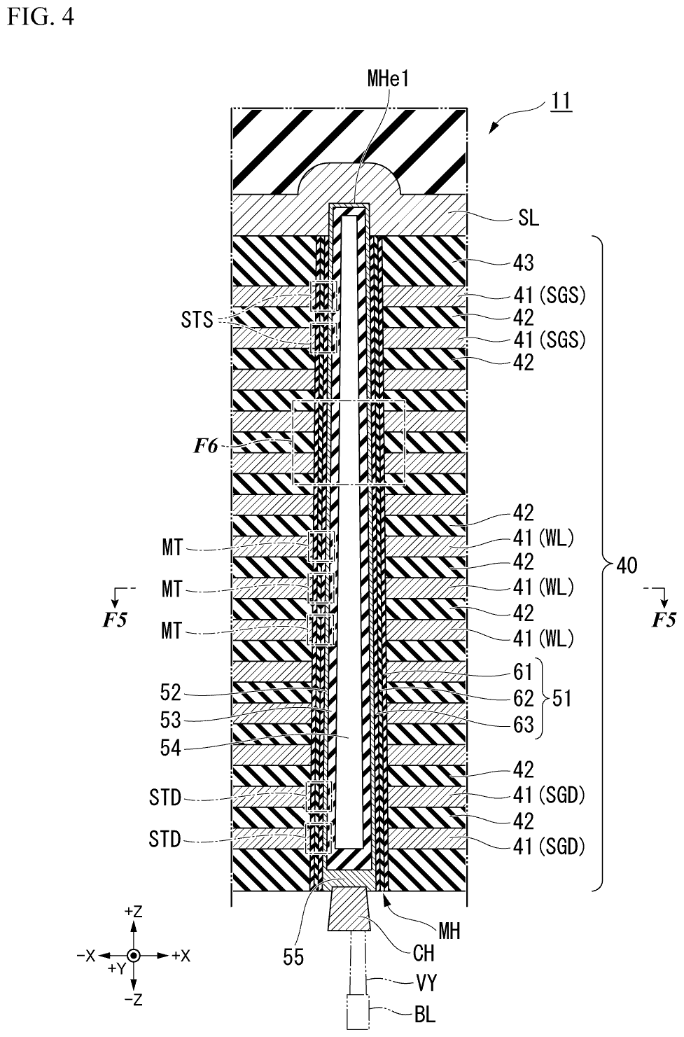

FIG. 4 is an enlarged cross-sectional view showing a region surrounded by line F4 of the memory cell array 11 shown in FIG. 3. The multi-layered body 40 includes, for example, the plurality of gate electrode layers 41, a plurality of insulating layers 42, an insulating layer 43, and an insulating portion 44. The plurality of gate electrode layers 41 and the plurality of insulating layers 42 are alternately stacked one by one in the Z direction.

The gate electrode layers 41 extend in the X direction and the Y direction. The gate electrode layers 41 each contain a conductive material (for example, tungsten, molybdenum, or silicon doped with impurities).

One or more (for example, a plurality of) gate electrode layers 41 positioned on a lower side among the plurality of gate electrode layers 41 function as the drain-side selection gate line SGD. The drain-side selection gate line SGD is commonly provided for the plurality of memory pillars MH aligned in the X direction or the Y direction. A portion in which the drain-side selection gate line SGD and a channel layer 52 (to be described later) of each memory pillar MH intersect functions as the drain-side selection transistor STD described above.

Of the plurality of gate electrode layers 41, one or more (for example, a plurality of) gate electrode layers 41 positioned on an upper side function as the source-side selection gate line SGS. The source-side selection gate line SGS is commonly provided for the plurality of memory pillars MH aligned in X direction or the Y direction. A portion in which the source-side selection gate line SGS and the channel layer 52 of each memory pillar MH intersect functions as the source-side selection transistor STS described above.

Of the plurality of gate electrode layers 41, the gate electrode layers provided between the gate electrode layer 41 functioning as the drain-side selection gate line SGD and the gate electrode layer 41 functioning as the source-side selection gate line SGS are the remaining gate electrode layers 41. These remaining gate electrode layers 41 may also be referred to as sandwiched gate electrode layers. At least a part of the remaining gate electrode layers 41 function as the word line WL. The word line WL is commonly provided for the plurality of memory pillars MH aligned in the X direction and the Y direction. In the present embodiment, a portion in which the word line WL and the channel layer 52 of each memory pillar MH intersect functions as the memory cell transistor MT. The memory cell transistor MT will be described in detail later. The insulating layer 42 is provided between two gate electrode layers 41 adjacent to each other in the Z direction. The insulating layer 42 is an interlayer insulating film that insulates the two gate electrode layers 41 from each other. The insulating layer 42 extends in the X direction and the Y direction. The insulating layer 42 is formed of, for example, a film containing silicon and oxygen (for example, a silicon oxide film).

The insulating layer 43 is an insulating layer provided above the gate electrode layer 41 disposed on an uppermost side. In other words, the insulating layer 43 may also be referred to as an insulating layer provided above the uppermost gate electrode layer. The insulating layer 43 is disposed between the gate electrode layer 41 disposed on an uppermost side and the source line SL. The insulating layer 43 extends in the X direction and the Y direction. The insulating layer 43 is formed of, for example, a film containing silicon and oxygen (for example, a silicon oxide film). For example, a thickness of the insulating layer 43 in the Z direction is larger than a thickness of the insulating layer 42 in the Z direction.

The insulating portion 44 is an insulating portion provided in the hook-up region FR to be described later. The insulating portion 44 covers end parts of the plurality of gate electrode layers 41 and the plurality of insulating layers 42 that are provided in a staircase shape from the side in the −Z direction. The insulating portion 44 is formed using, for example, tetraethyl orthosilicate (TEOS, Si(OC₂H₅)₄).

### 4.2 Source line

The source line SL is provided on the insulating layer 43. The source line SL is formed of, for example, a conductive layer or a semiconductor layer extending in the X direction and the Y direction. The source line SL is formed of a conductive material such as tungsten or molybdenum, or a semiconductor material including silicon.

### 4.3 Memory Pillar

The plurality of memory pillars MH are aligned in the X direction and the Y direction (refer to FIG. 3). The memory pillars MH each extend in the Z direction within the multi-layered body 40. The plurality of memory pillars MH penetrate the multi-layered body 40. The memory pillar MH is an example of a “columnar body”.

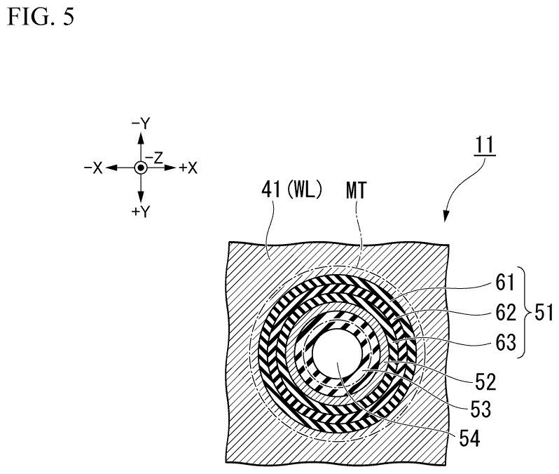

FIG. 5 is a cross-sectional view along line F5-F5 of the memory cell array 11 shown in FIG. 4. The memory pillar MH has, for example, a memory film (multilayer film) 51, the channel layer 52, an insulating portion 53, a hollow portion (air gap) 54, and a cap portion 55 (refer to FIG. 4).

The memory film 51 is provided on an outer circumferential side of the channel layer 52. The memory film 51 is positioned between the plurality of gate electrode layers 41 and the channel layer 52. The memory film 51 includes, for example, a block insulating film 61, a charge trap film 62, and a tunnel insulating film 63.

The block insulating film 61 is provided between the plurality of gate electrode layers 41 and the charge trap film 62. The block insulating film 61 is an insulating film that suppresses back tunneling. Back tunneling is a phenomenon in which charge returns from the word line WL to the charge trap film 62. The block insulating film 61 is formed in an annular shape. The block insulating film 61 extends in the Z direction. The block insulating film 61 is provided, for example, over the entire length of the memory pillar MH in the Z direction except for an end part MHe1 of the memory pillar MH on the side in the +Z direction to be described later. The block insulating film 61 is a stacked structure film. In the stacked structure film, a plurality of insulating films such as, for example, a film containing silicon and oxygen or a film containing a metal and oxygen are stacked. An example of the film containing a metal and oxygen is aluminum oxide film. The block insulating film 61 may contain a high dielectric constant material (high-k material) such as silicon nitride or hafnium oxide.

The charge trap film 62 is positioned between the block insulating film 61 and the tunnel insulating film 63. The charge trap film 62 is formed in an annular shape. The charge trap film 62 extends in the Z direction. The charge trap film 62 is provided, for example, over the entire length of the memory pillar MH in the Z direction except for the end part MHe1 of the memory pillar MH on the side in the +Z direction. The charge trap film 62 is a functional film that has a large number of crystal defects (trapping levels) and is capable of trapping charges in the crystal defects. The charge trap film 62 is formed of, for example, a film containing silicon and nitrogen. A part of the charge trap film 62 adjacent to each word line WL is an example of a “charge storage portion” capable of storing information by storing charges.

The tunnel insulating film 63 is provided between the channel layer 52 and the charge trap film 62. The tunnel insulating film 63 has, for example, an annular shape provided along an outer circumferential surface of the channel layer 52. The tunnel insulating film 63 extends in the Z direction along the channel layer 52. The tunnel insulating film 63 is provided, for example, over the entire length of the memory pillar MH in the Z direction except for the end part MHe1 of the memory pillar MH on the side in the +Z direction. The tunnel insulating film 63 is a potential barrier between the channel layer 52 and the charge trap film 62. The tunnel insulating film 63 is formed of a film containing silicon and oxygen, or a film containing silicon, oxygen, and nitrogen.

The channel layer 52 is provided inside the memory film 51. The channel layer 52 is formed in an annular shape. The channel layer 52 extends in the Z direction. The channel layer 52 is provided, for example, over the entire length of the memory pillar MH in the Z direction. The channel layer 52 is formed of a semiconductor material such as polysilicon. The channel layer 52 may be doped with impurities. When a voltage is applied to the word line WL, the channel layer 52 forms a channel to electrically connect the bit line BL and the source line SL.

Therefore, at a position of the same height as each word line WL, for example, a metal-Al-nitride-oxide-silicon (MANOS) type memory cell transistor MT is formed by an edge part of the word line WL adjacent to the memory pillar MH, the block insulating film 61, the charge trap film 62, the tunnel insulating film 63, and the channel layer 52. Note that, the memory film 51 may have a floating gate type charge storage portion (floating gate electrode) as the charge storage portion instead of the charge trap film 62. The floating gate type charge storage portion is formed of, for example, polysilicon silicon containing impurities.

The insulating portion 53 is provided inside the channel layer 52. At least a part of the inside of the channel layer 52 is filled with the insulating portion 53. The insulating portion 53 is formed of a film containing silicon and oxygen. In the present embodiment, the insulating portion 53 is formed in an annular shape along an inner circumferential surface of the channel layer 52 to form the hollow portion (air gap) 54 therein. Note that, the hollow portion 54 may not necessarily be present. The insulating portion 53 extends in the Z direction. The insulating portion 53 is provided, for example, over the entire length of the memory pillar MH in the Z direction except for an end part of the memory pillar MH on the side in the −Z direction (refer to FIG. 4).

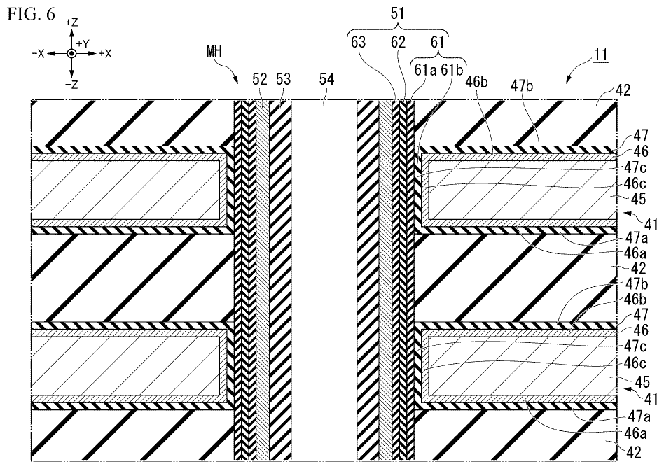

FIG. 6 is an enlarged cross-sectional view showing a region surrounded by line F6 of the memory cell array 11 shown in FIG. 4. In the present embodiment, each gate electrode layer 41 includes, for example, a conductive portion 45, a barrier metal film 46, and an insulating film 47.

The conductive portion 45 is a portion in which a main portion of the gate electrode layer 41 is formed. The conductive portion 45 extends in layers in the X direction and the Y direction. The conductive portion 45 contains the above-described conductive material (for example, tungsten, molybdenum, or silicon doped with impurities).

The barrier metal film 46 is a film for suppressing diffusion of the conductive material contained in the conductive portion 45. The barrier metal film 46 includes, for example, a material containing titanium, a material containing titanium and nitrogen, a material containing tantalum, a material containing tantalum and nitrogen, a material containing tungsten and nitrogen, or the like. The barrier metal film 46 is provided along a surface of the conductive portion 45. The barrier metal film 46 is provided between the conductive portion 45 and the insulating film 47. The barrier metal film 46 has a first film portion 46a, a second film portion 46b, and a third film portion 46c.

The first film portion 46a is provided between a surface of the conductive portion 45 on the side in the −Z direction and the insulating layer 42 positioned on the side in the −Z direction of the conductive portion 45. The first film portion 46a extends in the X direction and the Y direction along the surface of the conductive portion 45 on the side in the −Z direction.

The second film portion 46b is provided between a surface of the conductive portion 45 on the side in the +Z direction and the insulating layer 42 positioned on the side in the +Z direction of the conductive portion 45. The second film portion 46b extends in the X direction and the Y direction along the surface of the conductive portion 45 on the side in the +Z direction.

The third film portion 46c is provided along an edge of the conductive portion 45 facing the memory pillar MH. The third film portion 46c is positioned between the conductive portion 45 and the memory pillar MH. The third film portion 46c extends in the Z direction.

The insulating film 47 is an insulating film that improves a dielectric strength of the gate electrode layer 41. The insulating film 47 is formed of, for example, a film containing aluminum and oxygen (for example, an aluminum oxide film). The insulating film 47 is provided along a surface of the barrier metal film 46. The insulating film 47 is provided along a surface of the gate electrode layer 41. The insulating film 47 has a first film portion 47a, a second film portion 47b, and a third film portion 47c.

The first film portion 47a is provided between the first film portion 46a of the barrier metal film 46 and the insulating layer 42 positioned on the side in the −Z direction of the conductive portion 45. That is, the first film portion 47a is provided between the surface of the conductive portion 45 on the side in the −Z direction and the insulating layer 42 positioned on the side in the −Z direction of the conductive portion 45. The first film portion 47a extends in the X direction and the Y direction along a surface of the first film portion 46a of the barrier metal film 46.

The second film portion 47b is provided between the second film portion 46b of the barrier metal film 46 and the insulating layer 42 positioned on the side in the +Z direction of the conductive portion 45. That is, the second film portion 47b is provided between the surface of the conductive portion 45 on the side in the +Z direction and the insulating layer 42 positioned on the side in the +Z direction of the conductive portion 45. The second film portion 47b extends in the X direction and the Y direction along a surface of the second film portion 46b of the barrier metal film 46.

The third film portion 47c is provided between the third film portion 46c of the barrier metal film 46 and the charge trap film 62 of the memory pillar MH. That is, the third film portion 47c is provided between the edge of the conductive portion 45 facing the memory pillar MH and the charge trap film 62 of the memory pillar MH. The third film portion 47c extends in the Z direction along a surface of the third film portion 46c of the barrier metal film 46.

In the present embodiment, the block insulating film 61 includes a first portion 61a and a second portion 61b. The first portion 61a is formed in an annular shape along an outer circumference of the charge trap film 62. The first portion 61a extends in the Z direction. The first portion 61a is provided, for example, over the entire length of the memory pillar MH in the Z direction except for the end part MHe1 of the memory pillar MH on the side in the +Z direction.

On the other hand, the second portion 61b is formed by the third film portions 47c of the insulating films 47 of the plurality of gate electrode layers 41. The second portion 61b is formed in an annular shape to follow an outer circumference of the first portion 61a of the block insulating film 61. The second portion 61b is present corresponding to a height at which the gate electrode layer 41 is disposed. In the present embodiment, the block insulating film 61 is formed by the first portion 61a and the second portion 61b.

Next, returning to FIG. 4, the cap portion 55 will be described. The cap portion 55 is provided on a lower side of the insulating portion 53. The cap portion 55 is a semiconductor portion formed of a semiconductor material such as amorphous silicon or polysilicon. The cap portion 55 may be doped with impurities. The cap portion 55 is disposed on an inner circumferential side of an end part of the memory film 51 on the side in the −Z direction. The cap portion 55 is formed integrally with the channel layer 52. The cap portion 55, together with a lower end part of the channel layer 52, forms an end part of the memory pillar MH on the side in the −Z direction. The contact CH is in contact with the cap portion 55 from the side in the −Z direction.

Next, the end part MHe1 on the side in the +Z direction of the memory pillar MH will be described. In the present embodiment, the end part MHe1 of the memory pillar MH protrudes in the +Z direction from the multi-layered body 40. The end part MHe1 of the memory pillar MH is in contact with the source line SL. At the end part MHe1 of the memory pillar MH, the memory film 51 does not exist, and the channel layer 52 is exposed outside the memory pillar MH. Therefore, the channel layer 52 and the source line SL are connected.

### 4.4 Bit Line

Next, returning to FIG. 3, the bit line BL will be described. The bit line BL is an interconnection for selecting one memory pillar MH from among the plurality of memory pillars MH. The plurality of bit lines BL are disposed below (in the −Z direction) the multi-layered body 40. The plurality of bit lines BL are aligned in the X direction at intervals in the X direction. Each bit line BL extends in the Y direction. Each bit line BL extends to pass beneath the corresponding plurality of memory pillars MH.

Each bit line BL is connected to the channel layer 52 of the memory pillar MH via the contact VY and the contact CH. Therefore, the memory cell transistor MT can be optionally selected from among the plurality of memory cell transistors MT disposed three-dimensionally by combining the word line WL and the bit line BL.

### 4.5 Contact for Gate Electrode Layer

As shown in FIG. 3, the contact CC is an electrical connection portion that electrically connects the gate electrode layer 41 and the interconnection 72 (to be described later) included in the interconnection portion 70. The plurality of contacts CC are provided, for example, in the hook-up region FR of the memory cell array 11. The plurality of contacts CC extend in the Z direction within the multi-layered body 40. The plurality of contacts CC are connected to different gate electrode layers 41. The contact CC contains a conductive material (for example, tungsten, molybdenum, or silicon doped with impurities). The contact CC has conductivity. Note that, a structure of the hook-up region FR will be described in detail later.

### 4.6 Interconnection Portion

Next, the interconnection portion 70 will be described. The interconnection portion 70 is disposed, for example, between the multi-layered body 40 and the semiconductor substrate 21. The interconnection portion 70 includes, for example, a plurality of interconnections 71, a plurality of vias V1, and a plurality of interconnections 72.

The interconnection 71 is an electrical connection portion that electrically connects the bit line BL and the pad 32. The plurality of interconnections 71 are disposed below, for example, the plurality of bit lines BL. Each of the interconnections 71 extends, for example, in the X direction or the Y direction. The via V1 which electrically connects the interconnection 71 and the bit line BL is provided between the interconnection 71 and the bit line BL.

The interconnection 72 is an electrical connection portion that electrically connects the contact CC for a conductive layer and the pad 32. The interconnection 72 is electrically connected to the gate electrode layer 41 via the contact CC for a conductive layer. A voltage is applied to the interconnection 72 to select the gate electrode layer 41 (the word line WL, the drain-side selection gate line SGD, or the source-side selection gate line SGS).

### 4.7 Support

Next, the support HR will be described. The support HR is provided in the hook-up region FR. The support HR extends to penetrate the multi-layered body 40 in the Z direction in the hook-up region FR. The support HR is formed of, for example, an insulating material. The support HR supports the plurality of insulating layers 42 in a replacement process to be described below.

### 5. Dividing Portion

Next, the dividing portion 80 will be described.

FIG. 7 is a cross-sectional view along line F7-F7 of the semiconductor storage device 1 shown in FIG. 3. In the present embodiment, the plurality of dividing portions 80 are provided in the multi-layered body 40. The plurality of dividing portions 80 are disposed separately in the Y direction. The plurality of dividing portions 80 each extend in the Z direction within the multi-layered body 40 and divide one or more gate electrode layers 41 including a lowermost layer among the plurality of gate electrode layers 41 in the Y direction. The plurality of dividing portions 80 include, for example, a plurality of dividing portions ST and a plurality of dividing portions SHE.

### 5.1 Dividing Portion ST

The dividing portion ST is a wall portion that divides the multi-layered body 40 in the Y direction. The plurality of dividing portions ST are disposed separately in the Y direction. The dividing portion ST extends in the Z direction, penetrates the multi-layered body 40, and extends in the X direction. That is, the dividing portion ST is a wall portion provided in the Z direction and the X direction. The dividing portion ST divides each of all the gate electrode layers 41 included in the multi-layered body 40 in the Y direction.

### 5.2 Dividing Portion SHE

The dividing portion SHE is a dividing portion whose length in the Z direction is smaller than that of the dividing portion ST. The dividing portion SHE is a wall portion that divides a lower end part of the multi-layered body 40 in the Y direction. The plurality of dividing portions SHE are disposed separately in the Y direction. In the present embodiment, the plurality of (for example, four) dividing portions SHE are present between two dividing portions ST adjacent to each other in the Y direction. The dividing portion SHE is provided at a lower end part of the multi-layered body 40. The dividing portion SHE extends to a middle of the multi-layered body 40 in the Z direction, and also extends in the X direction. That is, the dividing portion SHE is a wall portion provided in the Z direction and the X direction.

The dividing portion SHE penetrates a part of the gate electrode layers 41 including a lowermost layer among the plurality of gate electrode layers 41. The dividing portion SHE divides the part of the gate electrode layer 41 in the Y direction.

For example, the dividing portion SHE penetrates each of all the gate electrode layers 41 functioning as the drain-side selection gate line SGD. On the other hand, the dividing portion SHE does not reach the gate electrode layer 41 functioning as the word line WL. The dividing portion SHE divides only the gate electrode layer 41 functioning as the drain-side selection gate line SGD in the Y direction. The dividing portion SHE is formed of, for example, a film containing silicon and oxygen.

### 6. Hook-Up Region

Next, the hook-up region FR will be described. In the drawings shown below, for convenience of explanation, a configuration related to six gate electrode layers 41 is extracted and shown.

### 6.1 Structure of Hook-Up Region

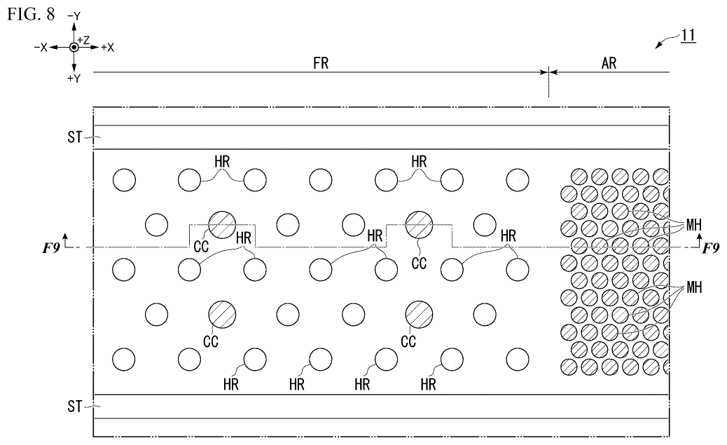

FIG. 8 shows a cross-sectional view of the memory cell array 11 from above. The hook-up region FR is a region in which no memory pillar MH is provided. The hook-up region FR has the plurality of contacts CC and a plurality of supports HR. The contact CC is an electrical connection portion that electrically connects the gate electrode layer 41 and the interconnection 72 included in the interconnection portion 70. The support HR is a support portion that supports the plurality of insulating layers 42 in the replacement process to be described later.

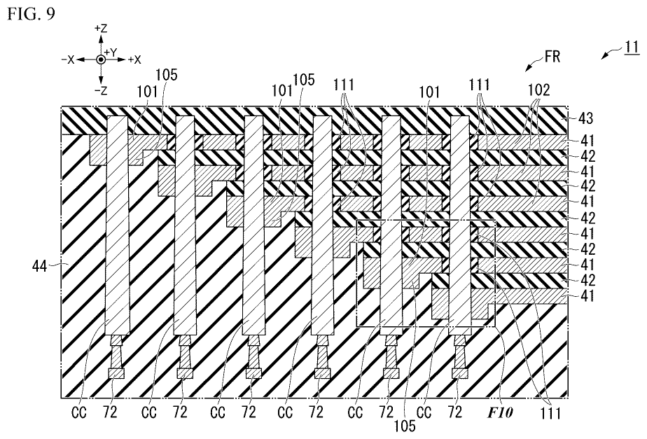

FIG. 9 is a cross-sectional view along line F9-F9 of the memory cell array 11 shown in FIG. 8. In the hook-up region FR, the plurality of gate electrode layers 41 have different lengths in the X direction. For example, regarding a length of each of the plurality of gate electrode layers 41 in the X direction, a length in the X direction of the gate electrode layer 41 positioned farther on the side in the −Z direction is smaller. In other words, regarding the plurality of gate electrode layers aligned in the Z direction, the length of each of the plurality of gate electrode layers 41 gradually increases toward the side in the −Z direction.

In the present embodiment, each gate electrode layer 41 has a terrace portion 101 and a non-terrace portion 102. The terrace portion 101 is a portion that does not overlap another gate electrode layer 41 positioned on the side in the −Z direction when viewed from the Z direction. The non-terrace portion 102 is a portion that overlaps another gate electrode layer 41 positioned on the side in the −Z direction when viewed from the Z direction.

In the present embodiment, the terrace portion 101 of each gate electrode layer 41 has a protruding portion 105 protruding in the −Z direction. A thickness of the terrace portion 101 in the Z direction at the portion in which the protruding portion 105 is present is larger than a thickness of the non-terrace portion 102 in the Z direction.

In the present embodiment, the plurality of contacts CC have the same length in the Z direction. Each of the contacts CC penetrates the multi-layered body 40 in the Z direction. Each contact CC extends in the Z direction to penetrate one or more (for example, a plurality of) gate electrode layers 41 that overlap the contact CC when viewed from the Z direction.

For example, when viewed from the Z direction, each contact CC is disposed at a position overlapping the protruding portion 105 of the gate electrode layer 41 to which the contact CC is to be connected. Each contact CC penetrates the protruding portion 105 of the gate electrode layer 41, to which the contact CC is to be connected, in the Z direction. Each contact CC penetrates the non-terrace portion 102 of the gate electrode layer 41 to which the contact CC is not to be connected (the gate electrode layer 41 that is not to be connected) in the Z direction.

Each contact CC is apart from the gate electrode layer 41 that is not to be connected. An insulating portion 111 is provided between each contact CC and the gate electrode layer 41 that is not to be connected. The insulating portion 111 is disposed at the same height as the gate electrode layer 41 that is not to be connected. The insulating portion 111 is formed in an annular shape along an outer circumference of the contact CC. Each contact CC is electrically insulated from the gate electrode layer 41 that is not to be connected by the insulating portion 111.

FIG. 10 is an enlarged cross-sectional view showing a region surrounded by line F10 of the memory cell array 11 shown in FIG. 9. FIG. 10 is shown inverted upside down relative to FIG. 9 for convenience of explanation. The plurality of gate electrode layers 41 include, for example, a first gate electrode layer 41A, a second gate electrode layer 41B, and a third gate electrode layer 41C. Among the plurality of gate electrode layers 41, the second gate electrode layer 41B is the gate electrode layer 41 disposed adjacent to the first gate electrode layer 41A on the side in the +Z direction. A length of the second gate electrode layer 41B in the X direction is larger than a length of the first gate electrode layer 41A in the X direction. Among the plurality of gate electrode layers 41, the third gate electrode layer 41C is the gate electrode layer 41 disposed adjacent to the second gate electrode layer 41B on the side in the +Z direction. A length of the third gate electrode layer 41C in the X direction is larger than the length of the second gate electrode layer 41B in the X direction.

The plurality of insulating layers 42 include a first insulating layer 42A and a second insulating layer 42B. The first insulating layer 42A is the insulating layer 42 disposed between the first gate electrode layer 41A and the second gate electrode layer 41B in the Z direction. The second insulating layer 42B is the insulating layer 42 disposed between the second gate electrode layer 41B and the third gate electrode layer 41C in the Z direction.

The plurality of contacts CC include a first contact CCA and a second contact CCB. The first contact CCA is the contact CC electrically connected to the first gate electrode layer 41A. The first contact CCA is disposed at a position overlapping the protruding portion 105 of the first gate electrode layer 41A when viewed from the Z direction. The first contact CCA penetrates the protruding portion 105 of the first gate electrode layer 41A in the Z direction. The first contact CCA penetrates the non-terrace portion 102 of the second gate electrode layer 41B and the non-terrace portion 102 of the third gate electrode layer 41C in the Z direction.

The second contact CCB is disposed farther away from the array region AR than the first contact CCA. The second contact CCB is the contact CC electrically connected to the second gate electrode layer 41B. The second contact CCB is disposed at a position overlapping the protruding portion 105 of the second gate electrode layer 41B when viewed from the Z direction. The second contact CCB penetrates the protruding portion 105 of the second gate electrode layer 41B in the Z direction. The second contact CCB penetrates the non-terrace portion 102 of the third gate electrode layer 41C in the Z direction.

Each contact CC has, for example, a columnar portion 121 and a bulging portion 122. The columnar portion 121 is formed, for example, in a columnar shape. The columnar portion 121 extends in the Z direction over the entire length of the contact CC in the Z direction. The bulging portion 122 is a portion that protrudes outward in the radial direction of the contact CC from a circumferential surface of the columnar portion 121. The bulging portion 122 is provided on a part of the contact CC in the Z direction. The bulging portion 122 of each contact CC is provided at the same height as the gate electrode layer 41 to which the contact CC is connected. The bulging portion 122 of each contact CC protrudes from the columnar portion 121 toward the gate electrode layer 41 to which the contact CC is connected. For example, the bulging portion 122 of the first contact CCA is provided at the same height as the first gate electrode layer 41A, and protrudes toward the first gate electrode layer 41A from the columnar portion 121. The bulging portion 122 of the second contact CCB is provided at the same height as the second gate electrode layer 41B, and protrudes toward the second gate electrode layer 41B from the columnar portion 121. The columnar portion 121 is an example of a “third conductive portion”. The columnar portion 121 may be referred to as a “first portion”. The bulging portion 122 is an example of a “fourth conductive portion”. The bulging portion 122 may be referred to as a “second portion”.

Also, each contact CC includes a conductive portion 125 and a barrier metal film 126.

The conductive portion 125 is a portion forming a main portion of the contact CC. The conductive portion 125 extends in the Z direction. The conductive portion 125 contains a conductive material (for example, tungsten, molybdenum, or silicon doped with impurities).

The barrier metal film 126 is a film for suppressing diffusion of the conductive material contained in the conductive portion 125. The barrier metal film 126 includes, for example, a material containing titanium, a material containing titanium and nitrogen, a material containing tantalum, a material containing tantalum and nitrogen, a material containing tungsten and nitrogen, or the like. The barrier metal film 126 is provided along a surface of the conductive portion 125. The barrier metal film 126 includes, for example, a first film portion 126a and a second film portion 126b. The first film portion 126a is provided on a surface of the columnar portion 121 of the contact CC. The second film portion 126b is provided on a surface of the bulging portion 122 of the contact CC.

FIG. 10 shows a virtual center line CL1 passing through a center of the first contact CCA in the X direction. Hereinafter, for convenience of explanation, the center of the first contact CCA in the X direction may be referred to as a “center CL1”. The center CL1 refers to a point positioned on the center line CL1.

### 6.2 First Gate Electrode Layer

Next, the first gate electrode layer 41A will be described. The first contact CCA penetrates the first gate electrode layer 41A in the Z direction. The first gate electrode layer 41A is adjacent to the bulging portion 122 of the first contact CCA in the X direction and the Y direction, and is in contact with the bulging portion 122 of the first contact CCA in the X direction and the Y direction. The first gate electrode layer 41A is connected to the bulging portion 122 of the first contact CCA in the X direction and the Y direction.

As described above, the first gate electrode layer 41A includes the conductive portion 45, the barrier metal film 46, and the insulating film 47. The conductive portion 45 of the first gate electrode layer 41A is an example of a “first conductive portion”. The barrier metal film 46 of the first gate electrode layer 41A is an example of a “first barrier metal film”. The insulating film 47 of the first gate electrode layer 41A is an example of a “first insulating film”.

The insulating film 47 of the first gate electrode layer 41A has the first film portion 47a and the second film portion 47b described above. The first film portion 47a of the first gate electrode layer 41A is provided along a surface of the first gate electrode layer 41A on the side in the −Z direction. A part of the first film portion 47a of the first gate electrode layer 41A extends in the X direction along a surface of the protruding portion 105 of the first gate electrode layer 41A. The second film portion 47b of the first gate electrode layer 41A is provided along a surface of the first gate electrode layer 41A on the side in the +Z direction. The second film portion 47b of the first gate electrode layer 41A is provided between the conductive portion 45 of the first gate electrode layer 41A and the first insulating layer 42A. The second film portion 47b extends in the X direction.

A shortest distance in the X direction between the insulating film 47 of the first gate electrode layer 41A and the center CL1 in the X direction of the first contact CCA is a distance L1. The distance L1 is defined by, for example, a shortest distance L1A or a shortest distance L1B described below.

The shortest distance L1A is a shortest distance in the X direction between the first film portion 47a of the first gate electrode layer 41A and the center CL1 in the X direction of the first contact CCA. The shortest distance L1B is a shortest distance in the X direction between the second film portion 47b of the first gate electrode layer 41A and the center CL1 in the X direction of the first contact CCA.

The barrier metal film 46 of the first gate electrode layer 41A has a fourth film portion 46d in addition to the first film portion 46a to the third film portion 46c described above. The fourth film portion 46d is provided between the conductive portion 45 of the first gate electrode layer 41A and the bulging portion 122 of the first contact CCA. The fourth film portion 46d extends in the Z direction. The fourth film portion 46d is in contact with the second film portion 126b of the barrier metal film 126 of the first contact CCA in the X direction. The first film portion 46a or the second film portion 46b is an example of a “first portion of the first barrier metal film”. The fourth film portion 46d is an example of a “second portion of the first barrier metal film”.

In the present embodiment, a boundary B is formed between the first contact CCA and the first gate electrode layer 41A. The boundary B is formed by at least one of the fourth film portion 46d of the barrier metal film 46 of the first gate electrode layer 41A and the second film portion 126b of the barrier metal film 126 of the first contact CCA.

### 6.2 Second Gate Electrode Layer

Next, the second gate electrode layer 41B will be described. The contact CCA and the contact CCB penetrate the second gate electrode layer 41B in the Z direction. The second gate electrode layer 41B is adjacent to the bulging portion 122 of the second contact CCB in the X direction and the Y direction. The second gate electrode layer 41B is in contact with the bulging portion 122 of the second contact CCB in the X direction and the Y direction. The second gate electrode layer 41B is connected to the bulging portion 122 of the second contact CCB in the X direction and the Y direction. On the other hand, the second gate electrode layer 41B is apart from the first contact CCA in the X direction and the Y direction. The insulating portion 111 is provided between the second gate electrode layer 41B and the first contact CCA.

As described above, the second gate electrode layer 41B includes the conductive portion 45, the barrier metal film 46, and the insulating film 47. The conductive portion 45 of the second gate electrode layer 41B is an example of a “second conductive portion”. The insulating film 47 of the second gate electrode layer 41B is an example of a “second insulating film”. The insulating film 47 of the second gate electrode layer 41B has a fourth film portion 47d in addition to the first film portion 47a to the third film portion 47c described above.

The first film portion 47a of the second gate electrode layer 41B is provided along a surface of the second gate electrode layer 41B on the side in the −Z direction. The first film portion 47a of the second gate electrode layer 41B is provided between the conductive portion 45 of the second gate electrode layer 41B and the first insulating layer 42A. The first film portion 47a extends in the X direction.

The second film portion 47b of the second gate electrode layer 41B is provided along a surface of the second gate electrode layer 41B on the side in the +Z direction. The second film portion 47b of the second gate electrode layer 41B is provided between the conductive portion 45 of the second gate electrode layer 41B and the second insulating layer 42B. The second film portion 47b extends in the X direction.

The fourth film portion 47d of the second gate electrode layer 41B extends in the Z direction across an edge of the first film portion 47a of the second gate electrode layer 41B and an edge of the second film portion 47b of the second gate electrode layer 41B. The fourth film portion 47d of the second gate electrode layer 41B is disposed adjacent to the insulating portion 111 in the X direction. The fourth film portion 47d is in contact with the insulating portion 111 in the X direction. The fourth film portion 47d of the second gate electrode layer 41B extends in the Z direction along the insulating portion 111.

A shortest distance between the insulating film 47 of the second gate electrode layer 41B and the center CL1 in the X direction of the first contact CCA is a distance L2. The distance L2 is defined by, for example, a shortest distance L2A, a shortest distance L2B, or a shortest distance L2C described below.

The shortest distance L2A is a shortest distance in the X direction between the first film portion 47a of the second gate electrode layer 41B and the center CL1 in the X direction of the first contact CCA. The shortest distance L2B is a shortest distance in the X direction between the second film portion 47b of the second gate electrode layer 41B and the center CL1 in the X direction of the first contact CCA. The shortest distance L2C is a shortest distance in the X direction between the fourth film portion 47d of the second gate electrode layer 41B and the center CL1 in the X direction of the first contact CCA.

### 6.3 Third Gate Electrode Layer

Next, the third gate electrode layer 41C will be described. The first contact CCA and the second contact CCB penetrate the third gate electrode layer 41C in the Z direction. For example, the third gate electrode layer 41C is apart from the first contact CCA in the X direction and the Y direction. The insulating portion 111 is provided between the third gate electrode layer 41C and the first contact CCA.

As described above, the third gate electrode layer 41C includes the conductive portion 45, the barrier metal film 46, and the insulating film 47. The insulating film 47 of the third gate electrode layer 41C has the fourth film portion 47d in addition to the first film portion 47a and the second film portion 47b described above.

The first film portion 47a of the third gate electrode layer 41C is provided along a surface of the third gate electrode layer 41C on the side in the −Z direction. The first film portion 47a of the third gate electrode layer 41C is provided between the conductive portion 45 of the third gate electrode layer 41C and the second insulating layer 42B. The first film portion 47a extends in the X direction.

The second film portion 47b of the third gate electrode layer 41C is provided along a surface of the third gate electrode layer 41C on the side in the +Z direction. The second film portion 47b of the third gate electrode layer 41C is provided between the conductive portion 45 of the third gate electrode layer 41C and another insulating layer 42 (the insulating layer 42 positioned on the side in the +Z direction of the third gate electrode layer 41C). The second film portion 47b extends in the X direction.

The fourth film portion 47d of the third gate electrode layer 41C extends in the Z direction across an edge of the first film portion 47a of the third gate electrode layer 41C and an edge of the second film portion 47b of the third gate electrode layer 41C. The fourth film portion 47d of the third gate electrode layer 41C is disposed adjacent to the insulating portion 111 in the X direction. The fourth film portion 47d is in contact with the insulating portion 111 in the X direction. The fourth film portion 47d of the third gate electrode layer 41C extends in the Z direction along the insulating portion 111. A shortest distance between the insulating film 47 of the third gate electrode layer 41C and the center CL1 in the X direction of the first contact CCA is a distance L3.

The distance L3 is the same as, for example, the distance L2 described above. The distance L3 is defined by, for example, a shortest distance L3A, a shortest distance L3B, or a shortest distance L3C described above.

The shortest distance L3A is a shortest distance between the first film portion 47a of the third gate electrode layer 41C and the center CL1 in the X direction of the first contact CCA. The shortest distance L3B is a shortest distance between the second film portion 47b of the third gate electrode layer 41C and the center CL1 in the X direction of the first contact CCA. The shortest distance L3C is a shortest distance between the fourth film portion 47d of the third gate electrode layer 41C and the center CL1 in the X direction of the first contact CCA.

### 6.4 Positional Relationship of Insulating Film

In the present embodiment, the shortest distance (the distance L1) in the X direction between the insulating film 47 of the first gate electrode layer 41A and the center CL1 in the X direction of the first contact CCA is smaller than the shortest distance (distance L2) in the X direction between the insulating film 47 of the second gate electrode layer 41B and the center CL1 in the X direction of the first contact CCA.

In the present embodiment, in at least a part of the region overlapping the protruding portion 105 of the first gate electrode layer 41A when viewed from the Z direction, the distance L1 is smaller than the distance L2. For example, the distance L1 is smaller than the distance L2 by 20 nm or more. However, the embodiment is not limited to the some examples of numerical values described above. Note that, in the following, some examples of dimensional relationships will be shown. However, the embodiment is not limited to the example having a structure with dimensional relationships described below. The embodiment may have a structure with dimensional relationships different from those described below.

From another perspective, a shortest distance (distance L11) in the X direction between the insulating film 47 of the first gate electrode layer 41A and the columnar portion 121 of the first contact CCA is smaller than a shortest distance (distance L12) in the X direction between the insulating film 47 of the second gate electrode layer 41B and the columnar portion 121 of the first contact CCA. For example, the distance L11 is half or less of the distance L12.

For example, the distance L11 is smaller than a thickness (for example, a maximum thickness) T1 of the terrace portion 101 of the first gate electrode layer 41A in the Z direction. On the other hand, the distance L12 is larger than the thickness (for example, the maximum thickness) T1 of the terrace portion 101 of the first gate electrode layer 41A in the Z direction.

For example, the distance L11 is smaller than a thickness (for example, a maximum thickness) T2 of the non-terrace portion 102 of the second gate electrode layer 41B in the Z direction. On the other hand, the distance L12 is larger than the thickness (for example, the maximum thickness) T2 of the non-terrace portion 102 of the second gate electrode layer 41B in the Z direction.

For example, the distance L11 is smaller than a thickness (for example, a maximum thickness) T3 of the first insulating layer 42A in the Z direction. On the other hand, the distance L12 is larger than the thickness (for example, the maximum thickness) T3 of the first insulating layer 42A in the Z direction.

From another perspective, the shortest distance (distance L1) in the X direction between the insulating film 47 of the first gate electrode layer 41A and the center CL1 in the X direction of the first contact CCA is smaller than the shortest distance (distance L4) in the X direction between the conductive portion 45 of the second gate electrode layer 41B and the center CL1 in the X direction of the first contact CCA.

From another perspective, a shortest distance (distance L5) in the X direction between the fourth film portion 46d of the barrier metal film 46 of the first gate electrode layer 41A and the center CL1 in the X direction of the first contact CCA is smaller than the shortest distance (distance L2) in the X direction between the insulating film 47 of the second gate electrode layer 41B and the center CL1 in the X direction of the first contact CCA. In the present embodiment, a shortest distance in the X direction between the above-described boundary B (the boundary between the first contact CCA and the first gate electrode layer 41A) and the center CL1 in the X direction of the first contact CCA corresponds to the distance L5 described above.

From another perspective, the shortest distance (distance L1) in the X direction between the insulating film 47 of the first gate electrode layer 41A and the center CL1 in the X direction of the first contact CCA is smaller than the shortest distance (distance L3) in the X direction between the insulating film 47 of the third gate electrode layer 41C and the center CL1 in the X direction of the first contact CCA.

Note that, the embodiment is not limited to the example described above. For example, the distance L1 may be the same as the distance L2 or the distance L3. The distance L11 may be the same as the distance L12. The distance L1 may be the same as the distance L4. The distance L5 may be the same as the distance L2.

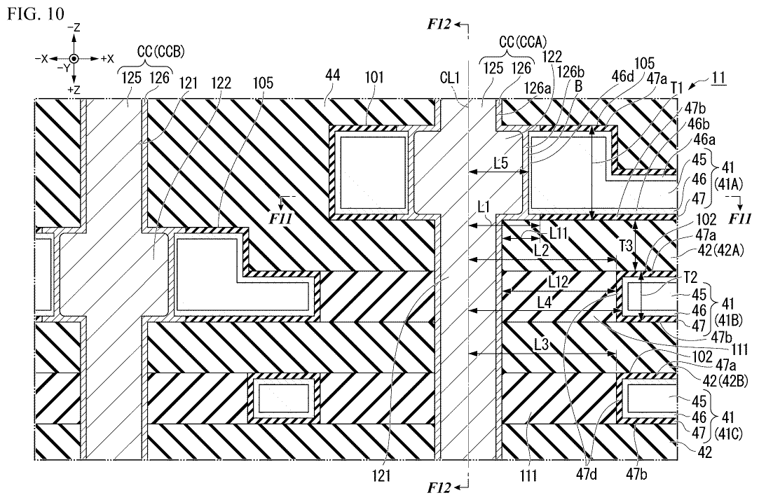

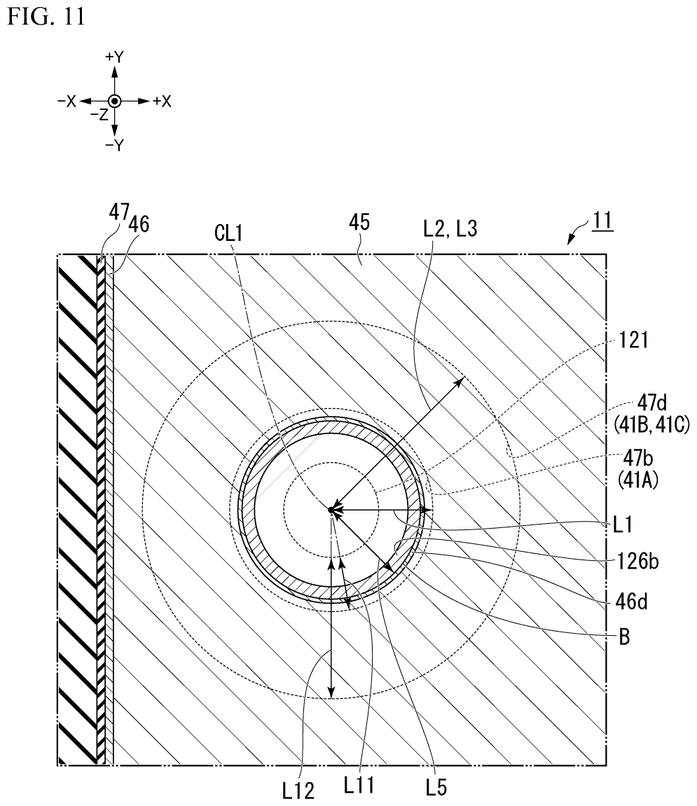

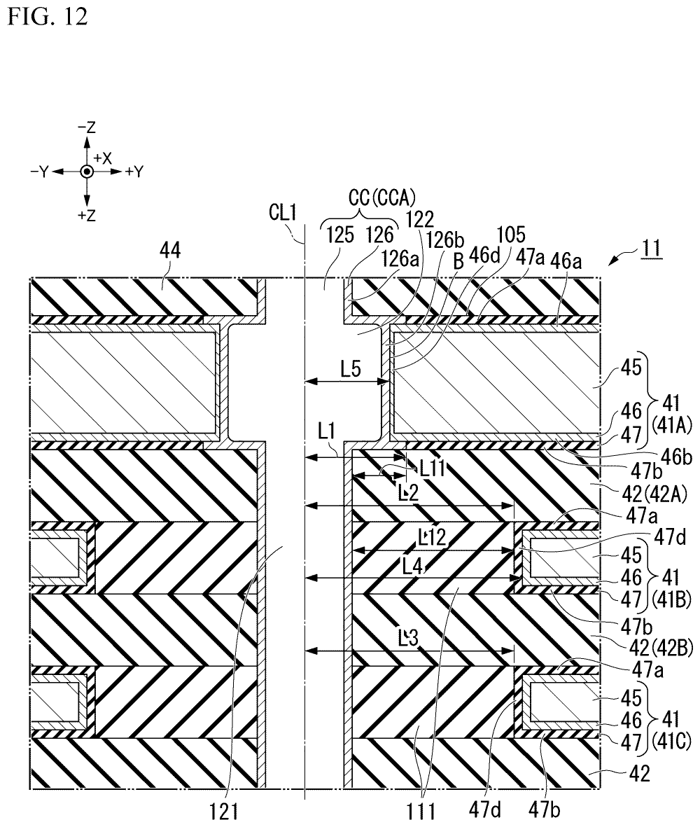

FIG. 11 is a cross-sectional view along line F11-F11 of the memory cell array shown in FIG. 10. In the present embodiment, edges of the first film portion 47a and the second film portion 47b (only the second film portion 47b is shown in FIG. 12) of the first gate electrode layer 41A are formed in an annular shape centered on the center line CL1. Also, the fourth film portion 46d of the second gate electrode layer 41B and the fourth film portion 46d of the third gate electrode layer 41C are formed in an annular shape centered on the center line CL1.

FIG. 12 is a cross-sectional view along line F12-F12 of the memory cell array shown in FIG. 10. In the present embodiment, the cross section in the Y direction (the cross section shown in FIG. 11) has the same configuration as the cross section in the X direction (the cross section shown in FIG. 10). Therefore, in the description regarding the cross section in the Y direction, the “X direction” in the above description of the cross section in the X direction need only be read as the “Y direction”.

### 7. Method of Manufacturing Semiconductor Storage Device

Next, a method of manufacturing the semiconductor storage device 1 will be described.

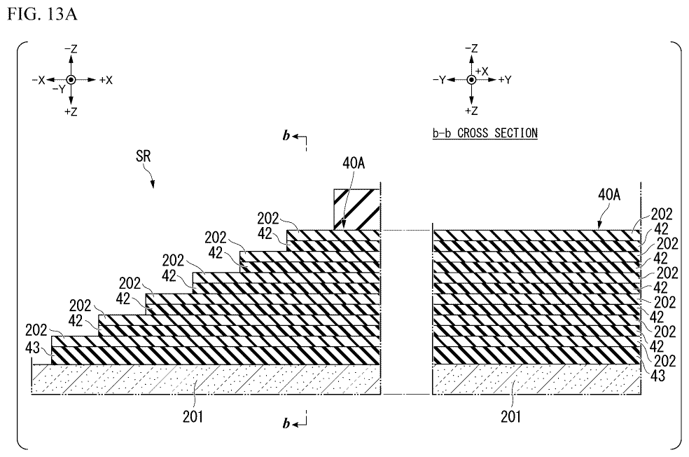

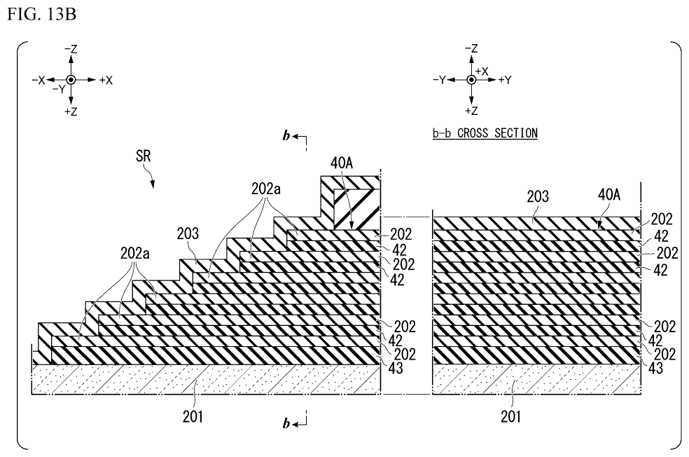

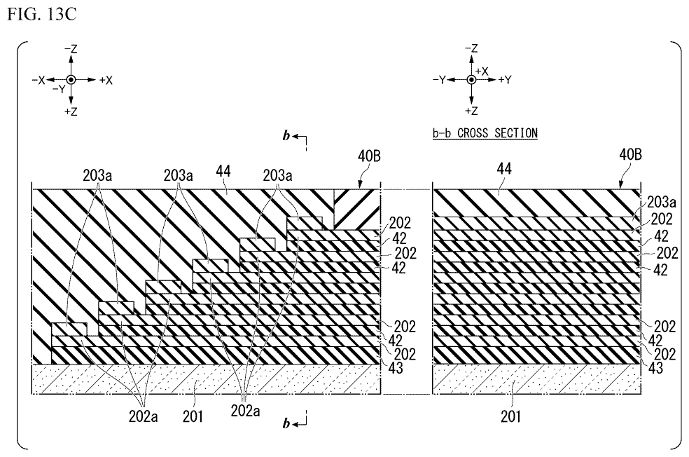

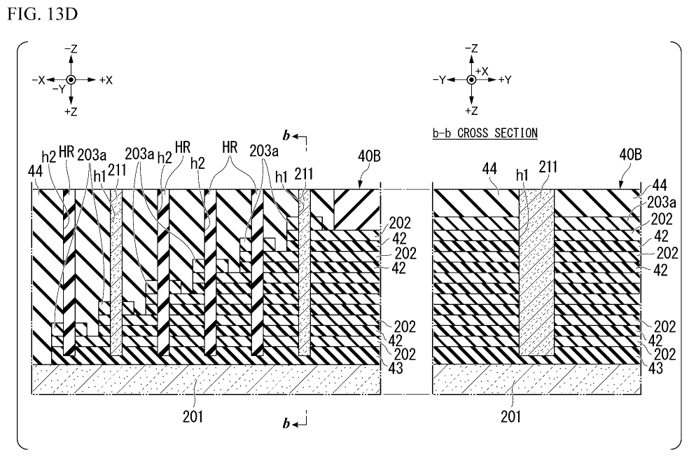

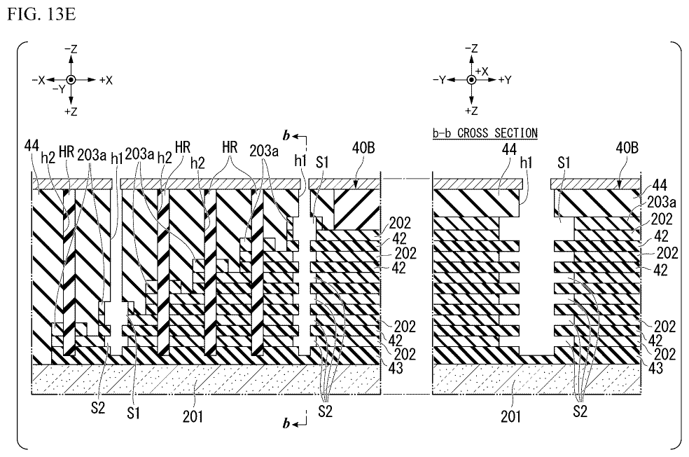

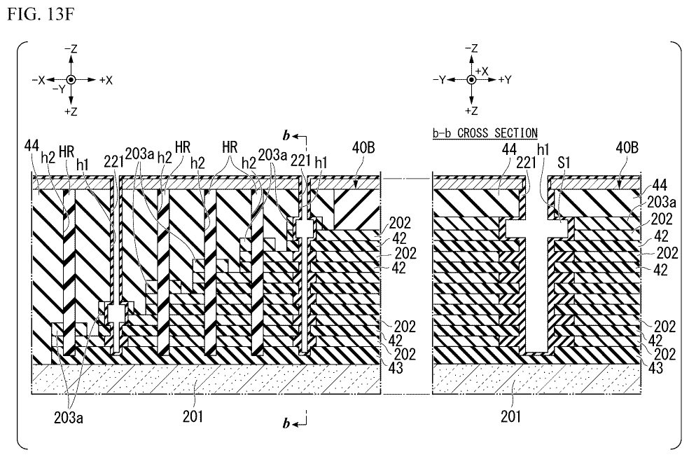

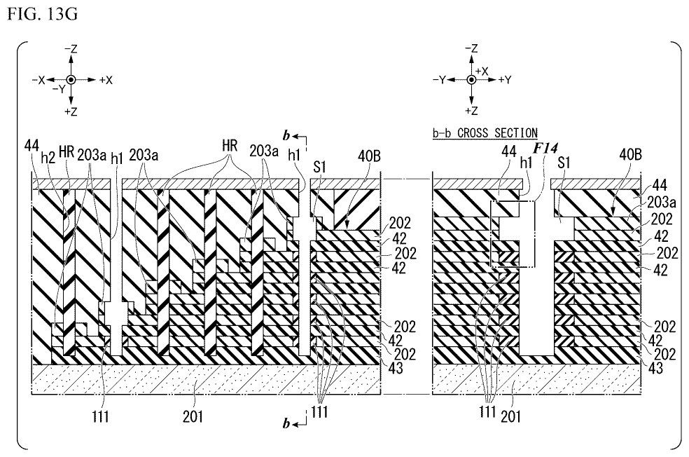

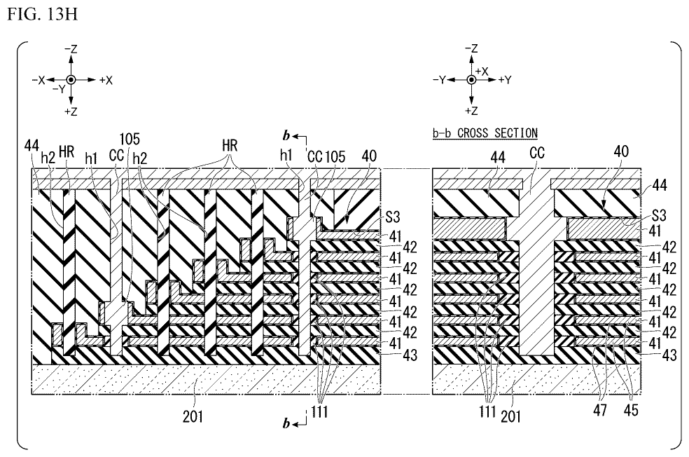

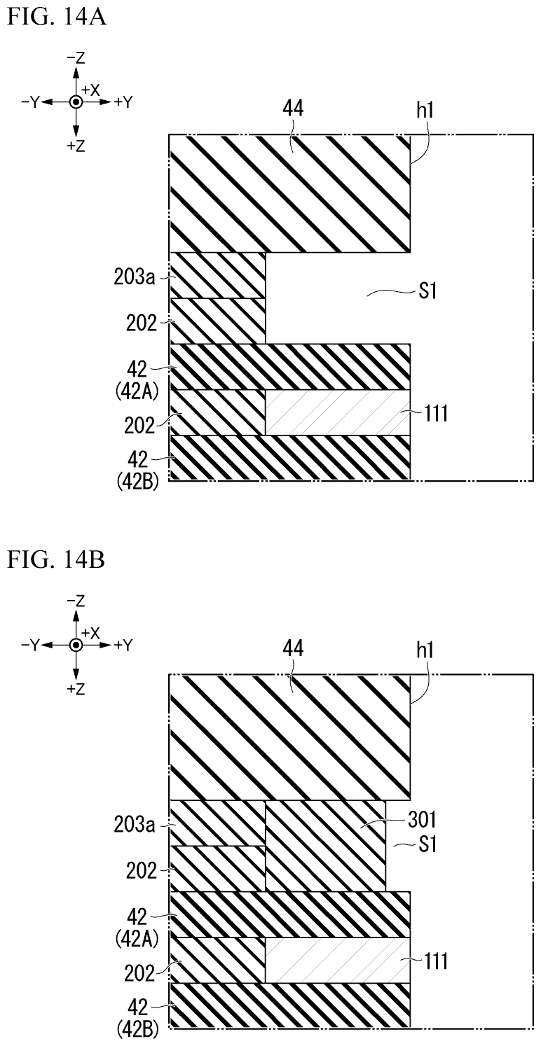

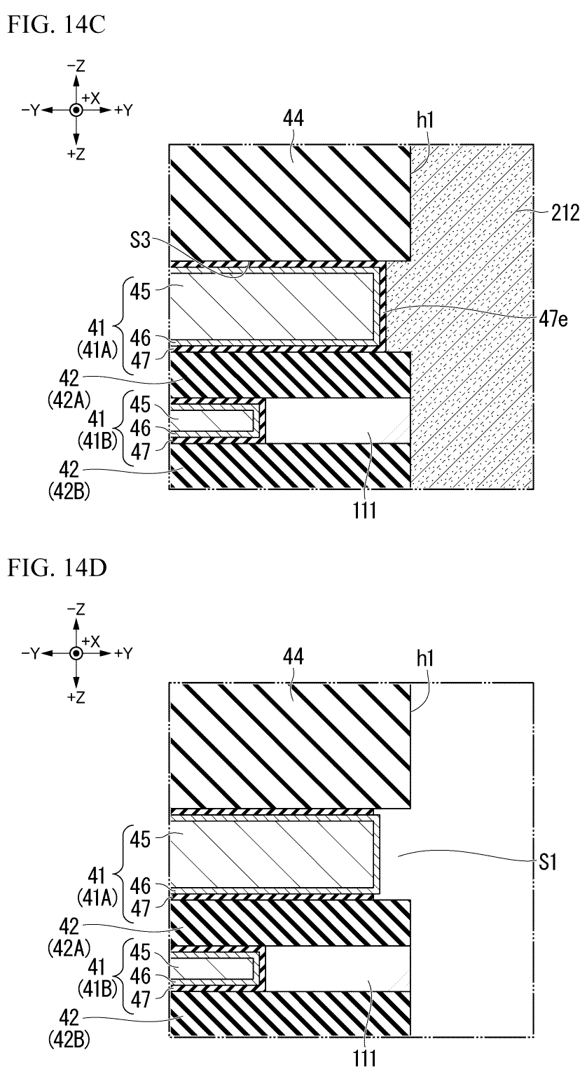

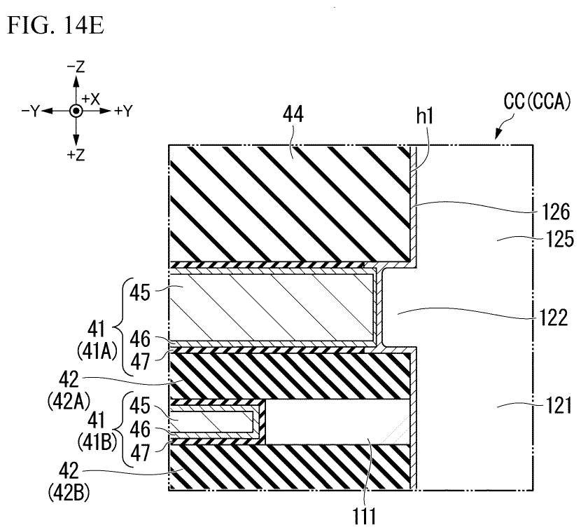

FIGS. 13A to 13H and 14A to 14E are cross-sectional views for explaining a method of manufacturing the semiconductor storage device 1. Note that, for convenience of explanation, the configurations shown on the left side in FIGS. 13A to 13H each show a cross section of the hook-up region FR taken along a cutting line in which both the contact CC and the support HR are shown.

First, an overall flow will be described with reference to FIGS. 13A to 13H.

As shown in FIG. 13A, the insulating layer 43 is formed on a semiconductor substrate 201. Next, insulating layers 202 and the insulating layers 42 are alternately stacked one by one on the insulating layer 43. The insulating layers 202 are, for example, sacrificial layers that are each replaced with the gate electrode layer 41 in the replacement process to be described later. The insulating layer 202 is formed of, for example, a film containing nitrogen and silicon (for example, a silicon nitride film).

Therefore, a multi-layered body 40A is formed. The insulating layer 202 is an example of a “first insulating layer”. The insulating layer 42 is an example of a “second insulating layer”.

Next, a resist (not shown in the drawings) is provided on the multi-layered body 40A, and unnecessary portions of the insulating layer 202 and the insulating layer 42 are removed by alternately repeating a resist slimming and a vertical processing by anisotropic etching. Therefore, a staircase region SR is provided in the multi-layered body 40A. In the staircase region SR, lengths of a plurality of insulating layers 202 in the X direction are different from each other.

Next, as shown in FIG. 13B, an insulating layer 203 is provided on each end part 202a of the plurality of insulating layers 202 in the staircase region SR. The insulating layer 203 is formed of, for example, the same insulating material as the insulating layer 202. The insulating layer 203 is formed of, for example, a film containing nitrogen and silicon (for example, a silicon nitride film).

Next, as shown in FIG. 13C, an unnecessary portion of the insulating layer 203 is removed by etching. Therefore, a plurality of insulating layers 203a are formed from the insulating layer 203. The insulating layers 203a are each formed on the end part 202a of the insulating layer 202. The insulating layer 203a is a sacrificial layer that is replaced with the protruding portion 105 of the gate electrode layer 41 in the replacement process to be described later. The insulating layer 203a is an example of a “third insulating layer”. Next, the insulating portion 44 is formed using TEOS to be implanted into the end part 202a of the insulating layer 202 and the insulating layer 203a in the staircase region SR. Therefore, a multi-layered body 40B is formed.

Next, as shown in FIG. 13D, a plurality of holes h1 for forming the contacts CC are formed in the multi-layered body 40B. The holes hl penetrate the multi-layered body 40B in the Z direction. Then, a semiconductor material (for example, amorphous silicon) is supplied into each of the holes h1. Therefore, a semiconductor portion 211 is formed inside the hole h1. The semiconductor portion 211 is a sacrificial portion that is replaced with the contact CC in a process to be described later. Similarly, a plurality of holes h2 for forming the supports HR are formed in the multi-layered body 40B. The holes h2 penetrate the multi-layered body 40B in the Z direction. Then, an insulating material is supplied into each of the holes h2. Therefore, the support HR is formed inside the hole h2.

Next, as shown in FIG. 13E, the semiconductor portion 211 is removed from the inside of the hole h1 by etching. Then, an edge part of the insulating layer 202 and an edge part of the insulating layer 203a adjacent to the hole h1 are removed by etching using the hole h1. Therefore, a first space S1 and a second space S2 that communicate with the hole h1 are provided inside the multi-layered body 40B. In the first space S1, the edge part of the insulating layer 203a and the edge part of the insulating layer 202 in contact with the insulating layer 203a are removed. Therefore, the first space S1 is formed in a region in which the edge part of the insulating layer 203a and the edge part of the insulating layer 202 in contact with the insulating layer 203a were present. The region is an example of a “first region”. On the other hand, the second space S2 is formed by removing an edge part of the insulating layer 202 that is not in contact with the insulating layer 203a . Therefore, the second space S2 is formed in a region in which the edge part of the insulating layer 202 was present. The region is an example of a “second region”. A width of the first space S1 in the Z direction is larger than a width of the second space S2 in the Z direction.

Next, as shown in FIG. 13F, an insulating material is supplied into the hole h1. Therefore, the second space S2 is filled with an insulating portion 221. The insulating portion 221 is provided along an inner surface of the hole h1 is formed. The insulating portion 221 is formed of, for example, a film containing silicon and oxygen (for example, a silicon oxide film). At this time, a width of the first space S1 in the Z direction is larger than a width of the second space S2 in the Z direction. Therefore, the inside of the first space S1 is not completely filled with the insulating portion 221.

Next, as shown in FIG. 13G, an unnecessary portion of the insulating portion 221 is removed by etching through the hole h1. Therefore, the insulating portion 111 is formed from the insulating portion 221 in a portion corresponding to the second space S2. The insulating portion 111 is an insulating portion. The second space S2 is filled with the insulating portion. The insulating portion 111 is an example of a “first insulating portion”. On the other hand, the insulating portion 221 present in the first space S1 is removed, and the first space S1 is formed again.

Next, as shown in FIG. 13H, a replacement process in which insulating layer 202 and insulating layer 203a are replaced with the gate electrode layer 41 is performed. For example, etching is performed through a groove (not shown in the drawings) (for example, a groove in which the dividing portion ST is formed) that penetrates the multi-layered body 40B in the Z direction, and the insulating layer 202 and the insulating layer 203a are removed. Therefore, a third space S3 corresponding to the insulating layer 202 and the insulating layer 203a is formed in the multi-layered body 40B.

Then, an insulating material for forming the insulating film 47 is first supplied into the third space S3 to form the insulating film 47. Next, a metal material for forming the barrier metal film 46 is supplied to the third space S3 to form the barrier metal film 46 (not shown in FIG. 13H). Next, a conductive material for forming the conductive portion 45 is supplied to the third space S3 to form the conductive portion 45. Therefore, the insulating layer 202 and the insulating layer 203a are replaced with the gate electrode layer 41. Next, the contact CC is formed by supplying a conductive material into the hole h1.

Next, the semiconductor substrate 201 is removed to form the second chip 3 (refer to FIG. 3). Then, the semiconductor storage device 1 is formed by adhering the first chip 2 and the second chip 3, which are separately prepared, together.

Next, a detailed flow of the manufacturing method will be described with reference to FIGS. 14A to 14E. FIGS. 14A to 14E are enlarged cross-sectional views showing the region surrounded by line F14 of the configuration shown in FIG. 13G. FIG. 14A is a view corresponding to the process of FIG. 13G. That is, the unnecessary portion of the insulating portion 221 is removed by etching through the hole h1. Therefore, the insulating portion 111 is formed. The second space S2 is filled with the insulating portion 111. The insulating portion 111 is an example of a “first insulating portion”. On the other hand, the insulating portion 221 present in the first space S1 is removed, and the first space S1 is formed again.

Next, as shown in FIG. 14B, an insulating material is supplied to the first space S1, and an insulating portion 301 that is continuous with the insulating layer 202 or the insulating layer 203a is formed. Therefore, at least a part of the first space S1 is backfilled with the insulating portion 301. The insulating portion 301 is formed of, for example, the same material as the insulating layer 202 or the insulating layer 203a . The insulating portion 301 is formed of, for example, a film containing nitrogen and silicon (for example, a silicon nitride film). The insulating portion 301 may be formed by selective growth using, for example, the insulating layer 202 and the insulating layer 203a as an underlayer. Alternatively, the insulating portion 301 may be formed, for example, by performing deposition to deposit an insulating material in the first space S1, and then performing etching that removes an unnecessary portion. Note that, the insulating portion 301 may be formed by a method different from that in the above-described example. The insulating portion 301 is an example of a “second insulating portion”.

Next, as shown in FIG. 14C, in a state in which the hole h1 is filled with a semiconductor portion 212, the above-described replacement process is performed. For example, the plurality of insulating layers 202, the plurality of insulating layers 203a , and the insulating portion 301 are removed to form the third space S3 in the multi-layered body 40B. Then, the gate electrode layer 41 is formed in the third space S3. Therefore, the first gate electrode layer 41A is formed to extend to a region in which the insulating portion 301 is provided in addition to the insulating layer 202 and the insulating layer 203a.

Next, as shown in FIG. 14D, the semiconductor portion 212 is removed by etching through the hole h1. Then, an edge part 47e (refer to FIG. 14C) of the insulating film 47 exposed to the first space S1 in the first gate electrode layer 41A is removed by etching through the hole h1. Therefore, the barrier metal film 46 or the conductive portion 45 is exposed to the first space S1.

Next, as shown in FIG. 14E, a metal material for forming the barrier metal film 126 of the contact CC is supplied to the hole h1 to form the barrier metal film 126. Next, a conductive material for forming the conductive portion 125 of the contact CC is supplied to the hole h1 to form the conductive portion 125 is formed. Therefore, the contact CC is formed inside the hole h1.

### 8. Advantages

As a comparative example, a semiconductor storage device manufactured by a process in which the insulating portion 301 is not provided will be considered. In a configuration of this comparative example, a part of the insulating film 47 of the first gate electrode layer 41A is removed in the process corresponding to FIG. 14D, and when compared to the insulating film 47 of the second gate electrode layer 41B, the insulating film 47 of the first gate electrode layer 41A may be present only in a region apart from the contact CC. In this case, a part of the conductive portion 45 or a part of the barrier metal film 46 of the first gate electrode layer 41A is left uncovered with the insulating film 47 in the +Z direction or the −Z direction. As a result, a dielectric strength between the first gate electrode layer 41A and the second gate electrode layer 41B may decrease, and electrical characteristics of the semiconductor storage device may deteriorate.

On the other hand, in the present embodiment, the semiconductor storage device 1 includes the multi-layered body 40 and the contact CCA. The multi-layered body 40 includes the plurality of gate electrode layers 41 and the plurality of insulating layers 42.

The plurality of gate electrode layers 41 include the first gate electrode layer 41A and the second gate electrode layer 41B. The contact CCA penetrates the first gate electrode layer 41A in the Z direction. The first gate electrode layer 41A is connected to the contact CCA in the X direction. The second gate electrode layer 41B is disposed adjacent to the first gate electrode layer 41A in the Z direction among the plurality of gate electrode layers 41. The contact CCA penetrates the second gate electrode layer 41B in the Z direction. The second gate electrode layer 41B is apart from the contact CCA in the X direction. The first gate electrode layer 41A has the conductive portion 45, and the insulating film 47. The insulating film 47 is provided between the conductive portion 45 and the first insulating layer 42A. The insulating film 47 includes a portion extending in the X direction. The second gate electrode layer 41B has the conductive portion 45, and the insulating film 47. The insulating film 47 is provided between the conductive portion 45 and the first insulating layer 42A. The insulating film 47 includes a portion extending in the X direction. The shortest distance (distance L1) in the X direction between the center CL1 in the X direction of the contact CCA and the insulating film 47 of the first gate electrode layer 41A is smaller than or equal to the shortest distance (distance L2) in the X direction between the center CL1 in the X direction of the contact CCA and the insulating film 47 of the second gate electrode layer 41B.

According to such a configuration, the first gate electrode layer 41A extends toward the inside of the contact CC to the same extent as or beyond the second gate electrode layer 41B. Therefore, an amount of the conductive portion 45 of the first gate electrode layer 41A covered with the insulating film 47 can be increased. Therefore, a dielectric strength between the first gate electrode layer 41A and the second gate electrode layer 41B is improved, and an improvement in electrical characteristics of the semiconductor storage device 1 can be achieved.

### 9. EXAMPLES

### 9.1 First Example

Next, a first example related to the above-described embodiment will be described.

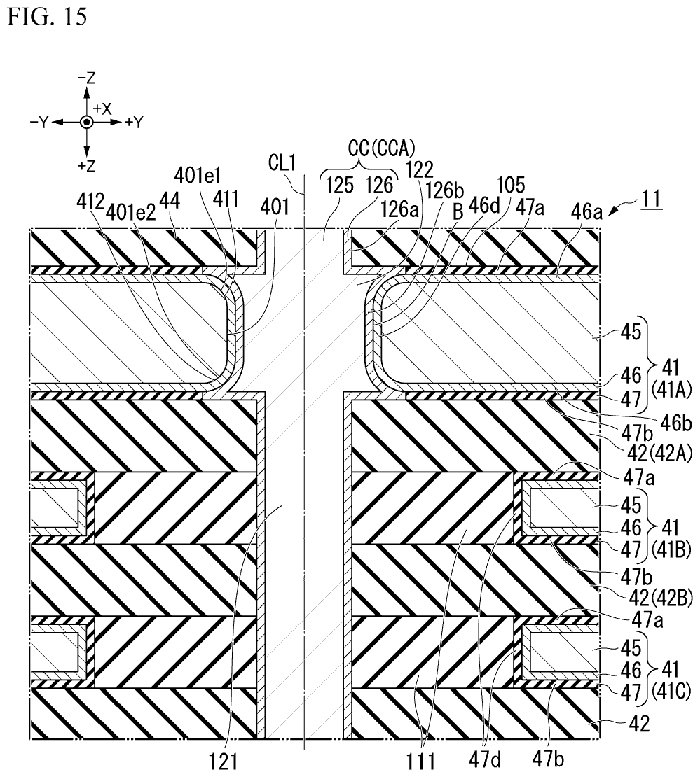

FIG. 15 is a cross-sectional view showing a part of a semiconductor storage device 1 of the first example. In the first example, the conductive portion 45 of the first gate electrode layer 41A has a first edge 401 facing the first contact CCA in the X direction and the Y direction. The first edge 401 has a first end part 401el on the side in the −Z direction and a second end part 401e2 on the side in the +Z direction. The first end part 401el has an arc-shaped curved portion 411 that inclines to the side in the −Z direction and protrudes toward the outside of the conductive portion 45. On the other hand, the second end part 401e2 has an arc-shaped curved portion 412 that inclines to side in the +Z direction and protrudes toward the outside of the conductive portion 45.

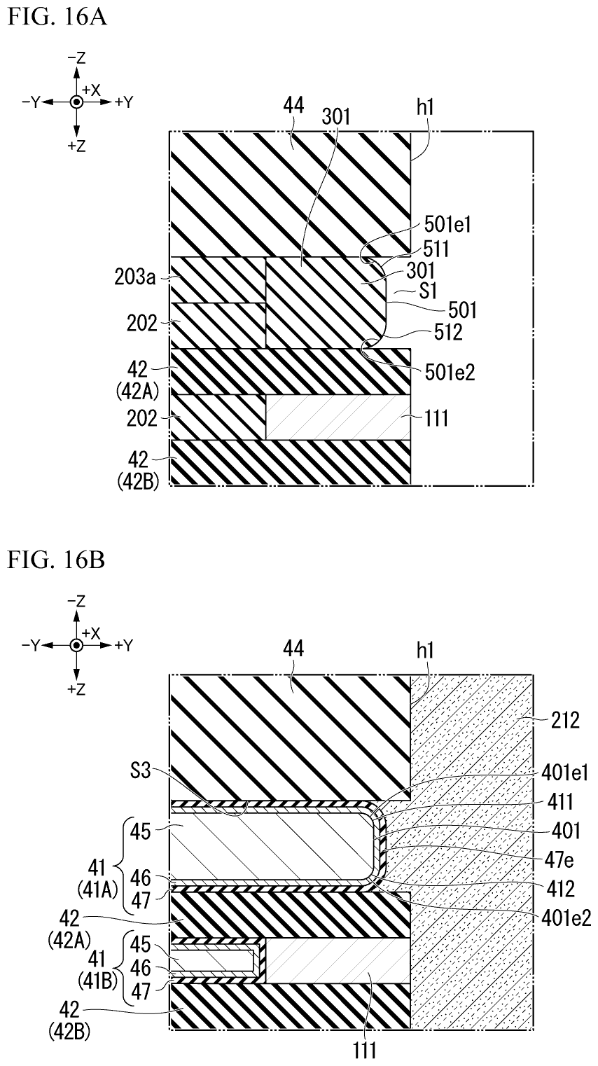

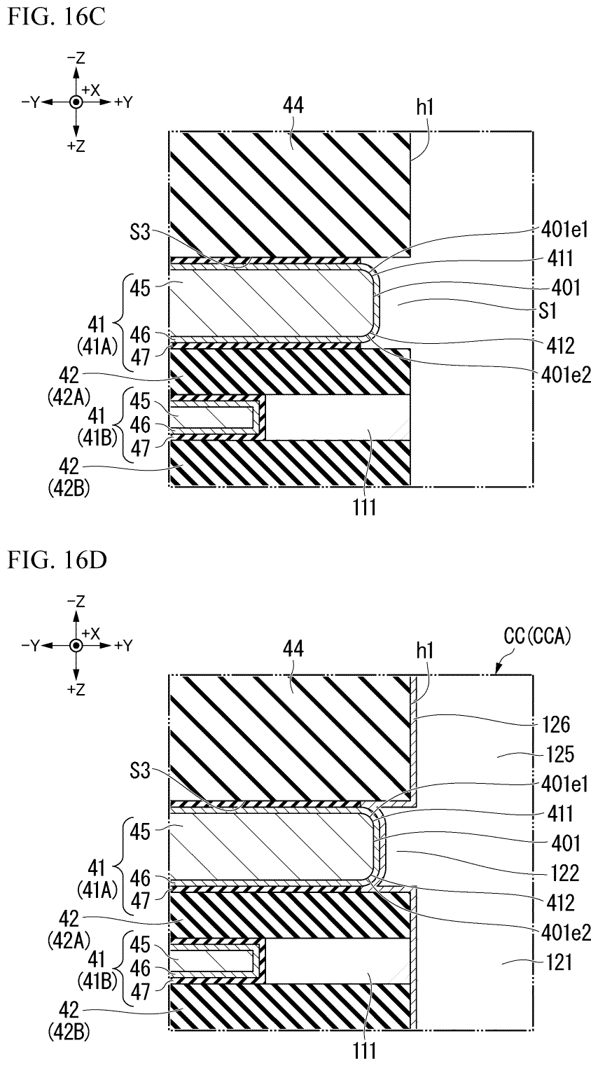

FIGS. 16A to 16D are cross-sectional views for explaining a method of manufacturing the semiconductor storage device 1 of the first example. The processes in FIGS. 16A to 16D correspond to the processes described in FIGS. 14B to 14E. As shown in FIG. 16A, in the present example, the insulating portion 301 is formed by selective growth using, for example, the insulating layer 202 and the insulating layer 203a as an underlayer.

In this case, the insulating portion 301 has a first edge 501 facing the first space S1 in the X direction and the Y direction. The first edge 501 has a first end part 501e1 on the side in the −Z direction and a second end part 501e2 on the side in the +Z direction. The first end part 501e1 has an arc-shaped curved portion 511 that inclines to the side in the −Z direction and protrudes toward the outside of the insulating portion 301.

On the other hand, the second end part 501e2 has an arc-shaped curved portion 512 that inclines to side in the +Z direction and protrudes toward the outside of the insulating portion 301.

In the present example, the insulating portion 301 having the curved portions 511 and 512 is replaced with a part of the first gate electrode layer 41A by a replacement process. Therefore, an outer shape of the first gate electrode layer 41A is rounded at a region corresponding to the curved portions 511 and 512 of the insulating portion 301.

### 9.2 Second Example

Next, a second example related to the above-described embodiment will be described.

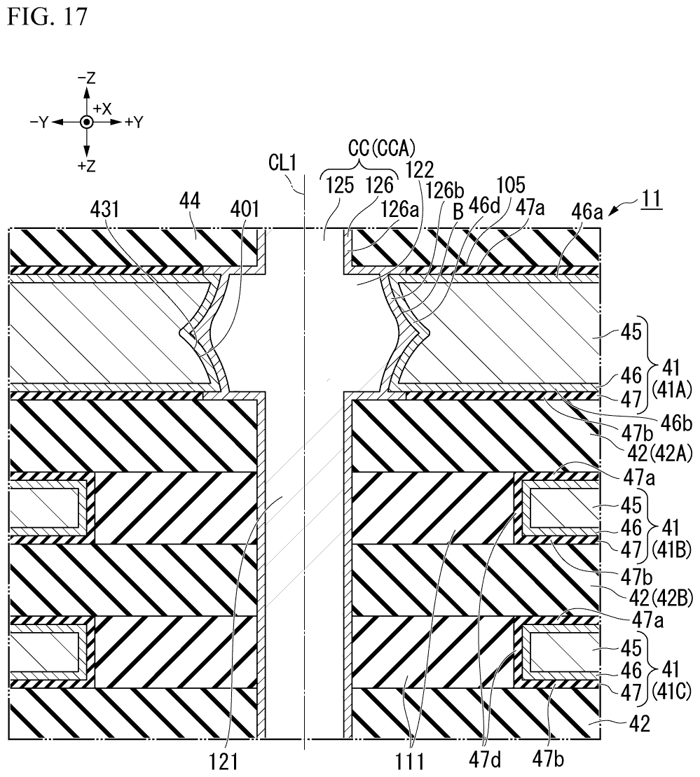

FIG. 17 is a cross-sectional view showing a part of a semiconductor storage device 1 of the second example. In the second example, the conductive portion 45 of the first gate electrode layer 41A has a first edge 401 facing the first contact CCA in the X direction and the Y direction. A central part of the first edge 401 in the Z direction has a recess 431 recessed in a direction away from the first contact CCA.

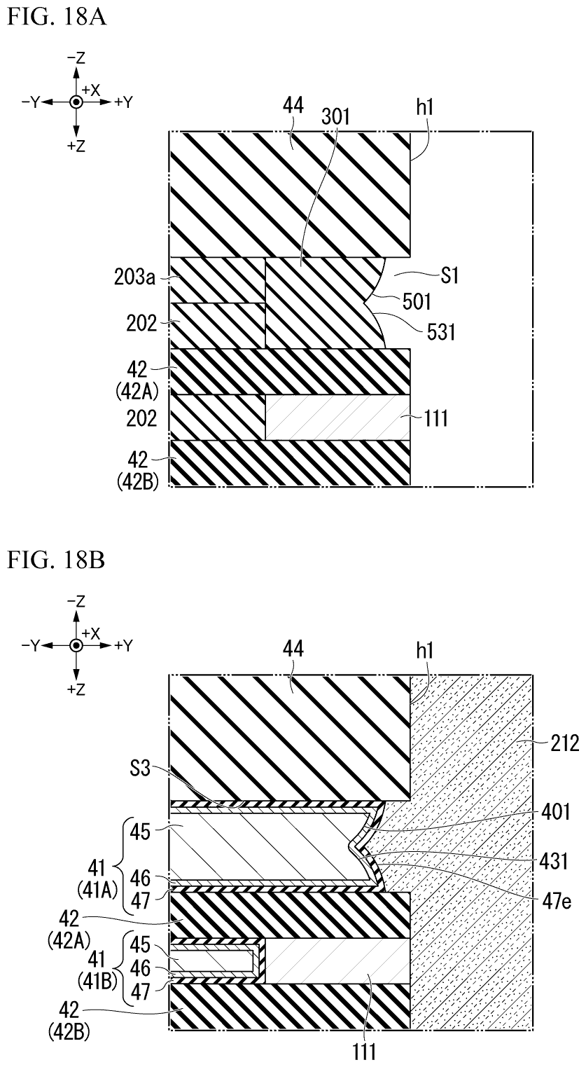

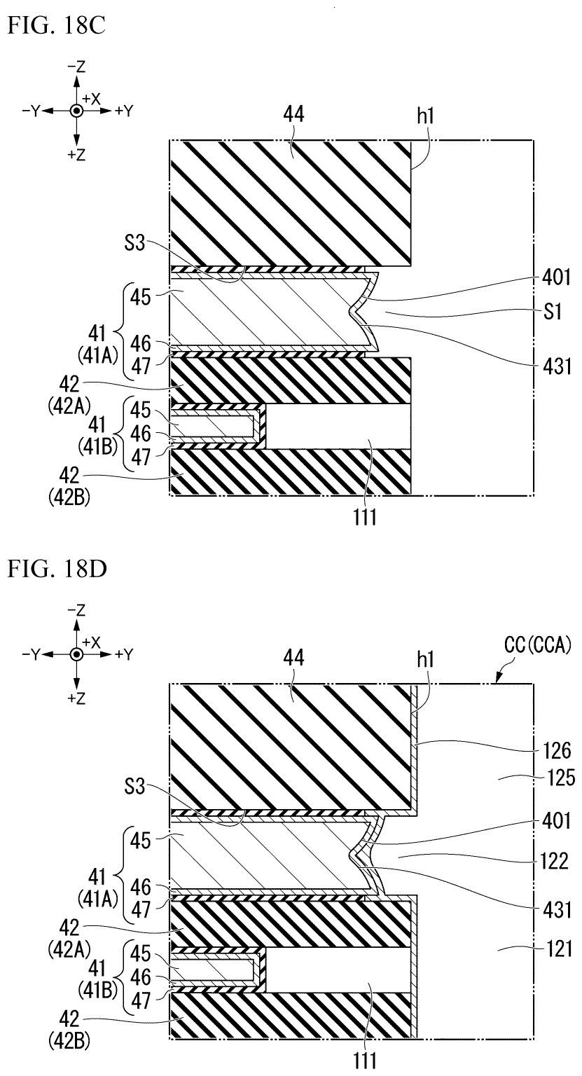

FIGS. 18A to 18D are cross-sectional views for explaining a method of manufacturing the semiconductor storage device 1 of the second example. The processes in FIGS. 18A to 18D correspond to the processes described in FIGS. 14B to 14E. As shown in FIG. 18A, in the present example, the insulating portion 301 is formed by performing deposition to deposit an insulating material in the first space S1, and then performing etching to remove an unnecessary portion.

In this case, the insulating portion 301 has a first edge 501 facing the first space S1 in the X direction and the Y direction. A central part of the first edge 501 in the Z direction has a recess 531 recessed in a direction away from the first space S1.

In the present example, the insulating portion 301 having the recess 531 is replaced with a part of the first gate electrode layer 41A by a replacement process.

Therefore, the first gate electrode layer 41A has a recess 431 in a region corresponding to the recess 531 of the insulating portion 301.

Although one embodiment and a plurality of examples have been described above, the embodiment and examples are not limited to the above-described examples.

According to at least one embodiment described above, a semiconductor storage device includes a multi-layered body and a contact. The multi-layered body includes a plurality of gate electrode layers and a plurality of insulating layers. The plurality of gate electrode layers include a first gate electrode layer and a second gate electrode layer.

The first gate electrode layer is connected to the contact in a second direction. The second gate electrode layer is apart from the contact in the second direction. The plurality of insulating layers include a first insulating layer between the first gate electrode layer and the second gate electrode layer in the first direction. The first gate electrode layer has a first conductive portion, and a first insulating film between the first conductive portion and the first insulating layer and including a portion extending in the second direction. The second gate electrode layer has a second conductive portion, and a second insulating film between the second conductive portion and the first insulating layer and including a portion extending in the second direction. A shortest distance in the second direction between the first insulating film and the contact is smaller than or equal to a shortest distance in the second direction between the second insulating film and the contact. According to such a configuration, an improvement in electrical characteristics of the semiconductor storage device can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a multi-layered body including a plurality of gate electrode layers and a plurality of insulating layers, the plurality of gate electrode layers and the plurality of insulating layers being alternately stacked one by one in a first direction; and
a contact extending in the first direction within the multi-layered body, the contact having conductivity, wherein
the plurality of gate electrode layers include:
a first gate electrode layer through which the contact penetrates in the first direction, the first gate electrode layer being connected to the contact in a second direction intersecting the first direction; and
a second gate electrode layer through which the contact penetrates in the first direction, the second gate electrode layer being adjacent to the first gate electrode layer in the first direction among the plurality of gate electrode layers, the second gate electrode layer being apart from the contact in the second direction,
the plurality of insulating layers include a first insulating layer, the first insulating layer being between the first gate electrode layer and the second gate electrode layer in the first direction,
the first gate electrode layer includes has a first conductive portion and a first insulating film, the first insulating film being between the first conductive portion and the first insulating layer, the first insulating film including a portion extending in the second direction,
the second gate electrode layer includes a second conductive portion and a second insulating film, the second insulating film being between the second conductive portion and the first insulating layer, the second insulating film including a portion extending in the second direction, and
a shortest distance in the second direction between a center of the contact in the second direction and the first insulating film is smaller than or equal to a shortest distance in the second direction between the center of the contact in the second direction and the second insulating film.

2. The semiconductor storage device according to claim 1, wherein
the shortest distance in the second direction between the center of the contact in the second direction and the first insulating film is smaller than or equal to a shortest distance in the second direction between the center of the contact in the second direction and the second conductive portion.

3. The semiconductor storage device according to claim 1, wherein
the multi-layered body has a hook-up region,
the plurality of gate electrode layers have different lengths in the second direction in the hook-up region,
in the hook-up region, a length of the first gate electrode layer in the second direction is smaller than a length of the second gate electrode layer in the second direction,
the first gate electrode layer has a protruding portion,
the protruding portion protrudes toward a side opposite to the second gate electrode layer in the hook-up region,
the contact penetrates the protruding portion in the first direction, and
in at least a part of a region overlapping the protruding portion when viewed from the first direction, the shortest distance in the second direction between the center of the contact in the second direction and the first insulating film is smaller than or equal to the shortest distance in the second direction between the center of the contact in the second direction and the second insulating film.

4. The semiconductor storage device according to claim 1, wherein
the contact has a columnar portion and a bulging portion,
the columnar portion extends in the first direction,
the bulging portion bulges from the columnar portion toward the first gate electrode layer, and
a shortest distance in the second direction between the columnar portion of the contact and the first insulating film is smaller than or equal to a shortest distance in the second direction between the columnar portion of the contact and the second insulating film.

5. The semiconductor storage device according to claim 4, wherein
a shortest distance in the second direction between the columnar portion of the contact and the first insulating film is half or less of a shortest distance in the second direction between the columnar portion of the contact and the second insulating film.

6. The semiconductor storage device according to claim 1, wherein
the first conductive portion has a first edge,
the first edge faces the contact in the second direction,
an end part of the first edge in the first direction has a curved portion,
the curved portion is inclined to a side in the first direction, and
the curved portion protrudes toward the outside of the first conductive portion.

7. The semiconductor storage device according to claim 1, wherein
the first conductive portion has a first edge,
the first edge faces the contact in the second direction,
the first edge has a central portion in the first direction, and
the central portion has a recess recessed in a direction away from the contact.

8. A method of manufacturing a semiconductor storage device, comprising:
stacking a first insulating layer and a second insulating layer alternately in a first direction, thereby forming a multi-layered body including a plurality of first insulating layers and a plurality of second insulating layers;
forming a staircase region, in which lengths of the plurality of first insulating layers are different in a second direction intersecting the first direction, in the multi-layered body;
forming a third insulating layer on an end part of each of the plurality of first insulating layers in the staircase region;
forming a hole, the hole penetrating the third insulating layer, the plurality of first insulating layers, and the plurality of second insulating layers in the first direction;
performing an etching through the hole, thereby removing an edge part of the third insulating layer adjacent to the hole and removing edge parts of the plurality of first insulating layers adjacent to the hole, thereby forming a first space in a first region and forming a second space in a second region, the edge part of the third insulating layer and the edge parts of the first insulating layers in contact with the third insulating layer being present in the first region, the edge part of the first insulating layer not in contact with the third insulating layer among the plurality of first insulating layers being present in the second region;
forming a first insulating portion, thereby the second space being filled with the first insulating portion;
forming a second insulating portion, the second insulating portion being continuous with the third insulating layer and the first insulating layer in at least a part of the first space; and
removing the second insulating portion, the third insulating layer, and the plurality of first insulating layers, thereby forming a third space, and forming a plurality of gate electrode layers each including an insulating film and a conductive portion in the third space.
